(19) United States
(12) Patent Application Publication
(10) Pub. No.: US 2021/0382401 A1
(43) Pub. Date: Dec. 9, 2021

(54) OVERLAY ALIGNMENT MARK, METHOD FOR MEASURING OVERLAY ERROR, AND METHOD FOR OVERLAY ALIGNMENT

(71) Applicant: Zhongke Jingyuan Electron Limited, Beijing (CN), Beijing (CN)

(72) Inventors: Chengcheng LIU, Beijing (CN); Chunying Han, Beijing (CN); Weimin MA, Beijing (CN); Shouyan Huang, Being (CN)

(21) Appl. No.: 17/332,571

(22) Filed: May 27, 2021

(30) Foreign Application Priority Data
Jun. 3, 2020 (CN) 202010495435.3

(51) Int. Cl. G03F 7/20; H01L 23/544; G03F 9/00

(52) U.S. Cl. CPC G03F 7/70633; H01L 2223/54426; G03F 9/7076; H01L 23/544

(57) ABSTRACT

An overlay alignment mark, a method for measuring overlay error, and a method for overlay alignment are provided in the embodiments of the present disclosure. the overlay alignment mark is formed on a wafer to be detected and comprises a first pattern and a second pattern, the first pattern being located in a first layer of the wafer and comprising two first solid sub-patterns which are provided opposite to each other in a first direction and extend in a second direction perpendicular to the first direction, respectively, and the second pattern being located in a second layer above the first layer of the wafer and comprising two first hollowed sub-patterns which are provided opposite to each other in the first direction and two to second hollowed sub-patterns which are provided opposite to each other in the second direction; and two opposite side edges of each of the two first solid sub-patterns extending in the second direction are at least partially exposed from a respective one of the two first hollowed sub-patterns.

### CROSS-REFERENCE TO RELATED APPLICATION

The present disclosure claims the benefit of Chinese Patent Application No. 202010495435.3 filed on Jun. 3, 2020 in the National Intellectual Property Administration of China, the whole disclosure of which is incorporated herein by reference.

### TECHNICAL FIELD

Embodiments of the present disclosure relates to the field of semiconductor manufacturing and detection, and more specifically to an overlay alignment mark(especially for SEM imaging), a method for measuring overlay error, and a method for overlay alignment.

### BACKGROUND

In manufacturing technology of semiconductor devices, mask patterns on a mask or a reticle are typically transferred onto a photoresist layer on a surface of a wafer, by lithography processes. And the lithography processes typically comprises following steps: photoresist coating, masking, exposure, development, and the like. With the continuous improvement of the integration degree of semiconductor devices, feature sizes of devices are decreasing continuously, and the processes become more and more complex. In order to achieve superior device performance, there exist strict requirements on feature sizes of lithography patterns in various layers. In order to reduce sizes of semiconductor devices, typically, in addition to increasing layout density of devices by reducing linewidth of devices, the integration degree of devices is further improved by increasing specific number of layers processed by lithography, for example. Therefore, in multi-layer lithography processes, alignment between and/or among various process layers is one of the basic requirements of the production processes, then, it is necessary to measure and to correct overlay error between layers in order to achieve required overlay accuracy and ensure accurate and precise overlay alignment between layers. The overlay error represents positional offset of respective patterns in various layers, and the overlay accuracy is usually assessed by the overlay error between two layers or among three layers. The overlay accuracy not only depends on the positioning accuracy and processing accuracy of a machine table/stage, but also depends on the perfection in control applied by a control system.

The importance of overlay accuracy for both lithography process and yield is self-evident; therefore, the detection of overlay error and the control on overlay accuracy are particularly important. In relevant art, typically the detection of the overlay accuracy is carried out by setting overlay alignment marks in different layers, at least partially overlapping two overlay alignment marks with each other, and obtaining an overlay error between the two overlay alignment marks by obtaining an offset amount in alignment by measuring an offset value therebetween. And then a correction is performed on the basis of the overlay error, and then an alignment between respective lithographic patterns of two layers is facilitated by maintaining overlapping and alignment of patterns of the two alignment marks.

The embodiment of the present disclosure more specifically relates to the measurement of CDSEM, that is, measurement of critical dimensions (CDs) of patterns by using a SEM apparatus. CD values as measured by the SEM apparatus may for example comprise sizes of photoresist pattern formed after exposure and development thereof. Only when the SEM measurement results meet requirements, subsequent processes such as ion implantation or etching or the like can be carried out. As for the measurement of CDSEM, it is usually required to carry out an alignment by means of an optical microscope above all, then, based on the alignment with SEM, the measurement of CD value is implemented with SEM. In order to implement the alignment using SEM, it is necessary to set the overlay alignment mark for SEM.

### SUMMARY

Embodiments of the present disclosure have been made to overcome or alleviate at least one aspect of the above mentioned defects and/or deficiencies in the relevant art, by providing an overlay alignment mark a method for measuring overlay error, and a method for overlay alignment.

Following technical solution are provided in exemplary embodiments of the disclosure:

According to a first aspect of the embodiments of the disclosure, there is provided an overlay alignment mark formed on a wafer to be detected, comprising a first pattern and a second pattern, the first pattern being located in a first layer of the wafer and comprising two first solid sub-patterns which are provided opposite to each other in a first direction and extend in a second direction perpendicular to the first direction, respectively, and the second pattern being located in a second layer above the first layer, of the wafer and comprising two first hollowed sub-patterns which are provided opposite to each other in the first direction and two second hollowed sub-patterns which are provided opposite to each other in the second direction; two opposite side edges of each of the two first solid sub-patterns extending in the second direction are at least partially exposed from a respective one of the two first hollowed sub-patterns.

According to exemplary embodiments of the present disclosure, the two first solid sub-patterns are designed to be in the form of two solid patterns having strip-shaped sections, both of which not only have central symmetry, to each other, about a first reference point located therebetween, but also have mirror symmetry to each other with respect to the first reference point; one type of the two first hollowed sub-patterns and the two second hollowed sub-patterns is designed to be in the form of two through-holes having rectangular sections, which not only have central symmetry to each other about a second reference point located therebetween but also have mirror symmetry to each other with respect to the second reference point; and a coordinate value of the first reference point in the first direction and a coordinate value of the second reference point in the first direction are set such that a difference between these two coordinate values is a first constant.

According to exemplary embodiments of the present disclosure, an overlay error between different layers of the wafer is an overlay error between the first layer and the second layer, at least comprising: a deviation between the first layer and the second layer in the first direction, which is defined by subtracting the first constant from a deviation between the first pattern and the second pattern in the first direction.

In addition, according to another aspect of the embodiments of the disclosure, there is provided a method for measuring overlay error, comprising: providing the overlay alignment mark as above; and measuring an overlay error between different layers of the wafer by measuring a deviation between portions of the overlay alignment mark which portions are located in the different layers of the wafer.

In addition, according to still another aspect of the embodiments of the disclosure, there is provided a method for overlay alignment, comprising: performing the method for measuring overlay error as above; and compensating for the overlay error between different layers of the wafer, by offsetting the different layers of the wafer relative to each other.

In addition, according to yet another aspect of the embodiments of the disclosure, there is provided a method for measuring overlay error, comprising: providing an overlay alignment mark on a wafer whose overlay error is to be detected; and measuring an overlay error between different layers of the wafer by measuring a deviation between portions of the overlay alignment mark which portions are located in the different layers of the wafer. The step of “providing an overlay alignment mark on a wafer whose overlay error is to be detected” comprises providing a first pattern and providing a second pattern, “providing a first pattern” comprising: providing two first solid sub-patterns in a first layer of the wafer, the two first solid sub-patterns being provided opposite to each other in a first direction and extending in a second direction perpendicular to the first direction, respectively; and “providing a second pattern” comprising: providing two first hollowed sub-patterns and two second hollowed sub-patterns in a second layer above the first layer of the wafer, the two first hollowed sub-patterns being provided opposite to each other in the first direction, and two second hollowed sub-patterns being provided opposite to each other in the second direction, two opposite side edges of each of the two first solid sub-patterns which extend in the second direction being at least partially exposed from a respective one of the two first hollowed sub-patterns.

### BRIEF DESCRIPTION OF THE DRAWINGS

Embodiments of the disclosure are depicted merely by way of example, by referring to accompanying schematic drawings at present, wherein corresponding reference numerals in the drawings represent corresponding components. The drawings are briefly depicted as follows:

FIG. 1(a) shows a schematic top view of an overlay alignment mark according to embodiments of the present disclosure;

FIG. 1(b) shows a schematic top view of a typical example of the overlay alignment mark as described in FIG. 1(a);

FIG. 2(a) and FIG. 2(b) show sectional views cut along sectional lines A-A′ and B-B′ in FIG. 1(a), respectively;

FIG. 3(a) and FIG. 3(b) show, in top views, portions of the overlay alignment mark as illustrated in FIG. 1(a) which are located respectively in the second layer as a current layer and in the first layer as a previous layer;

FIG. 4 schematically shows that an overlay error between two different layers are calculated depending on the overlay alignment mark as illustrated in FIG. 1(a), according to embodiments of the present disclosure;

FIG. 5 schematically shows that an overlay error between two different layers are obtained depending on existing patterns provided with sub-patterns in the arrangement as illustrated in FIG. 4, according to embodiments of the present disclosure, without forming a specialized/dedicated overlay alignment mark;

FIG. 6 shows a schematic top view of an overlay alignment mark according to other embodiments of the present disclosure;

FIG. 7(a) and FIG. 7(b) illustrate sectional views which are cut along section lines A-A′ and B-B′ as shown in FIG. 6, respectively;

FIG. 8(a) and FIG. 8(b) illustrate, in top views, portions of the overlay alignment mark as illustrated in FIG. 6, in the second layer functioning as the current layer and in the first layer functioning as the previous layer, respectively;

FIG. 9 schematically shows that, the overlay error between two different layers is obtained, with the overlay alignment mark as illustrated in FIG. 6, according to embodiments of the present disclosure;

FIG. 10 shows in more detail that, based on the overlay alignment mark as arranged in FIG. 9, the coordinate value of symmetrical center of the portion of overlay alignment mark as illustrated in FIG. 6 located in the first layer is calculated;

FIG. 11 shows in more detail a first way by which the coordinate values of the symmetrical center of the portion of the overlay alignment mark (as illustrated in FIG. 6) located in the second layer can be obtained, based on the overlay alignment mark as arranged in FIG. 9;

FIG. 12 shows in more detail a second way by which the coordinate values of the symmetrical center of the portion of the overlay alignment mark (as illustrated in FIG. 6) located in the second layer can be obtained, based on the overlay alignment mark as arranged in FIG. 9;

FIG. 13 shows in more detail a third way by which the coordinate values of the symmetrical center of the portion of the overlay alignment mark (as illustrated in FIG. 6) located in the second layer can be obtained, based on the overlay alignment mark as arranged in FIG. 9;

FIG. 14(a) and FIG. 14(b) show schematic top views of a first arrangement and a second arrangement of overlay alignment marks according to further embodiments of the present disclosure;

FIG. 15(a) and FIG. 15(b) show sectional views cut along the section lines A-A′ and B-B′ in FIG. 14(a), respectively;

FIG. 15(c) and FIG. 15(d) show sectional views cut along the section lines A-A′ and B-B′ in FIG. 14(b), respectively;

FIG. 16(a) to FIG. 16(c) show, in top views, portions of the overlay alignment mark as illustrated in FIG. 14(a) which are located in the second layer (functioning as the current layer), in the first layer (functioning as the previous layer), and in the third layer (functioning as the second previous layer), respectively;

FIG. 16(d) to FIG. 16(f) show, in top views, portions of the overlay alignment mark as illustrated in FIG. 14(b) which are located in the second layer (functioning as the current layer), in the third layer (functioning as the previous layer), and in the first layer (functioning as the second previous layer), respectively;

FIG. 17(a) schematically shows that, the overlay error among three different layers is obtained, with the overlay alignment mark as illustrated in FIG. 14(a), according to embodiments of the present disclosure;

FIG. 17(b) schematically shows that, the overlay error among three different layers is obtained, with the overlay alignment mark as illustrated in FIG. 14(b), according to embodiments of the present disclosure;

FIG. 18(a) shows in more detail that, based on the overlay alignment mark as arranged in FIG. 17(a), the coordinate values of symmetrical centers of portions of overlay alignment mark located in the first layer and in the third layer respectively as illustrated in FIG. 14(a) are calculated;

FIG. 18(b) shows in more detail that, based on the overlay alignment mark as arranged in FIG. 17(b), the coordinate values of symmetrical centers of portions of overlay alignment mark located in the first layer and in the third layer respectively as illustrated in FIG. 14(b) are calculated;

FIG. 19(a) shows in more detail a first way by which the coordinate values of the symmetrical center of the portion of the overlay alignment mark (as illustrated in FIG. 14(a)) located in the second layer can be obtained, based on the overlay alignment mark as arranged in FIG. 17(a);

FIG. 19(b) shows in more detail a first way by which the coordinate values of the symmetrical center of the portion of the overlay alignment mark (as illustrated in FIG. 14(b)) located in the second layer can be obtained, based on the overlay alignment mark as arranged in FIG. 17(b);

FIG. 20(a) shows in more detail a second way by which the coordinate values of the symmetrical center of the portion of the overlay alignment mark (as illustrated in FIG. 14(a)) located in the second layer can be obtained, based on the overlay alignment mark as arranged in FIG. 17(a);

FIG. 20(b) shows in more detail a second way by which the coordinate values of the symmetrical center of the portion of the overlay alignment mark (as illustrated in FIG. 14(b)) located in the second layer can be obtained, based on the overlay alignment mark as arranged in FIG. 17(b);

FIG. 21 shows a method for measuring overlay error according to an embodiment of the present disclosure;

FIG. 22(a) shows a schematic block diagram of step S101 of the method for measuring overlay error as shown in FIG. 21 in a condition that the overlay alignment mark is formed in two layers;

FIG. 22(b) shows a schematic block diagram of step S101 of the method for measuring overlay error as shown in FIG. 21 in a condition that the overlay alignment mark is formed in three layers;

FIG. 23(a) shows a schematic block diagram of step S102 of the method for measuring overlay error shown in FIG. 21 in some embodiments of the present disclosure;

FIG. 23(b) shows a schematic block diagram of step S102 of the method for measuring overlay error shown in FIG. 21 in some other embodiments of the present disclosure;

FIG. 23(c) shows a schematic block diagram of step S102 of the method for measuring overlay error as shown in FIG. 21 in further more embodiments of the present disclosure;

FIG. 24 shows an overlay alignment method according to an embodiment of the present disclosure.

### DETAILED DESCRIPTION OF EMBODIMENTS

The technical scheme of the present disclosure will be further explained in detail in combination with the accompanying drawings. In the specification, the same or similar reference numerals and letters indicate the same or similar parts. The following description of embodiments of the present disclosure with reference to the accompanying drawings is intended to explain the general inventive concept of the present disclosure and should not be construed as a limitation of the present disclosure.

The drawings are used to illustrate the contents of the present disclosure. Respective dimension and shape of each of components in the drawings are only intended to exemplarily illustrate the contents of the disclosure, rather than to demonstrate the practical dimension or proportion of components used in various layers of the semiconductor devices and overlay alignment mark according to embodiments of the present disclosure.

In relevant art, during the implementation of multilayer lithography processes, the overlay error is usually obtained by measuring an overlay alignment mark for multilayer in two-dimensional directions (direction X and direction Y) of a plane parallel to the substrate of the wafer, respectively. Moreover, in the relevant art, the implementation of CDSEM measurement for multi-layer lithography processes usually requires a coarse alignment by using an optical microscope above all, and then a fine alignment by using a SEM apparatus, and then the SEM apparatus is used to measure CD values. In order to realize the alignment with SEM, it is required to set the overlay alignment mark of the SEM apparatus reasonably.

As to the setup of overlay alignment mark in relevant art, two factors as follows should be taken into account, i.e., firstly, a set of fixed overlay alignment marks should be used to measure the overlay error in two orthogonal directions (e.g., direction X and direction Y) at the same time; secondly, the overlay accuracy between multiple layers should be measured by measuring the overlay error between multiple layers (two or more layers). However, more specifically, when using SEM images to measure multilayer overlay accuracy in relevant art, for example, in a condition that merely an overlay alignment mark in the form of a linear pattern is provided, typically, respective patterns of portions of the overlay alignment mark in various layers are arranged such that their respective orthographic projections on the wafer (e.g., on the substrate thereof) are expected to be staggered with respect to each other, and thus an offset amount between different layers during alignment thereof can be obtained subsequently by measuring a distance between portions of the overlay alignment mark on different layers; and in such a condition, for example, SEM patterns are acquired layer by layer and then are stacked on each other so as to perform a calculation on the offset amount during alignment, then an interference on the measurement of the overlay error may be easily introduced due to a deviation between or among multiple-positioning of the SEM apparatus in the process of multiple acquisition and superposition/stacking. Moreover, upon setting the overlay alignment mark for measuring the overlay error, a problem concerning energy of electron beams existing in acquisition of the SEM images is typically not taken into account in the prior art, i.e., upon acquiring the SEM images, the setting of the energy of electron beams may directly influence image clarity/definition of the SEM images and the cost of the SEM apparatus. Furthermore, upon measuring the overlay error between two layers or among three layers in a condition that merely an overlay alignment mark in the form of a linear pattern is provided, if SEM images of the same clarity/definition are expected to be obtained for both a condition of two layers and another condition of three layers, then respective energies of electron beams as required in different conditions are different from each other. As such, energy of the electron beams being set excessively low may result in an insufficient resolution of images; and energy of the electron beams being set excessively high may result in an increase in the cost of the apparatus.

In addition, in the method for measuring overlay error in relevant art, the overlay error is calculated by detecting edges of images, and in turn by directly calculating deviation between edges of respective patterns of various layers based on the edges of respective patterns of various layers as extracted from SEM image(s), without image processing on image noise introduced during a detection process of said edges of the respective patterns;

therefore, due to the influence of image noise, measurement result in the prior art has some losses in the aspect of accuracy and stability as compared with that in an ideal condition.

Therefore, there is an urgent need for an improved overlay alignment mark in the art, which may reach a compromise of meeting requirements in overlay accuracy of an accurate measurement at a relatively saved energy of electron beams, and effectively reduce an impact of image noise, during acquisition of SEM images for measuring the overlay error.

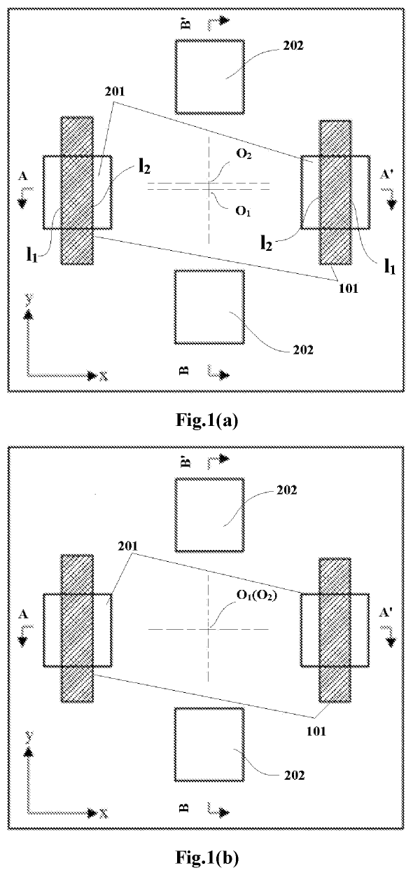

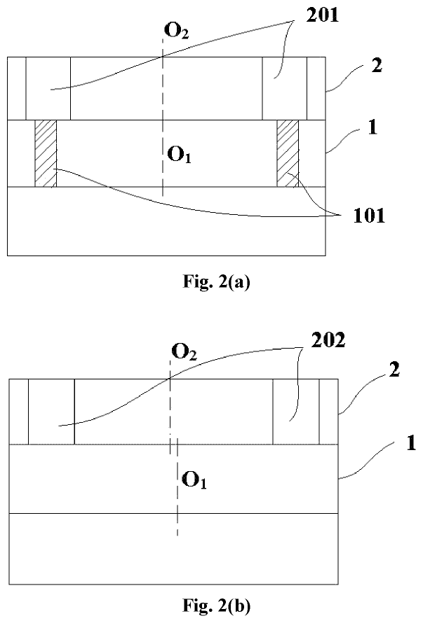

FIG. 1(a) shows a schematic top view of an overlay alignment mark according to embodiments of the present disclosure; FIG. 2(a) and FIG. 2(b) show sectional views cut along sectional lines A-A′ and B-B′ in FIG. 1(a). According to a general technical concept of embodiments of the disclosure, in one aspect of embodiments of the disclosure, an overlay alignment mark formed in a wafer is provided, the wafer is for example to be imaged by scanning thereon by SEM. More specifically, by way of example, a specific layered arrangement of the overlay alignment mark shown in FIG. 1(a) is schematically illustrated in FIG. 2(a) and FIG. 2(b), where the overlay alignment mark comprises a first pattern 10 which is located in the first layer 1 of the wafer; and a second pattern 20, which is located in the second layer 2 above the first layer 1 of the wafer. The first pattern 10 comprises two first solid sub-patterns 101 provided opposite to each other in a first direction (e.g., a horizontal direction X of the rectangular coordinate system as a reference coordinate system as illustrated in the lower left corner of FIG. 1(a)) and extending in a second direction (e.g., the vertical direction Y of the rectangular coordinate system as the reference coordinate system as illustrated in the lower left corner of FIG. 1(a)) perpendicular to the first direction respectively. And the second pattern 20 comprises: two first hollowed sub-patterns 201 provided opposite to each other in the first direction X; and two second hollowed sub-patterns 202 provided opposite to each other in the second direction Y. Furthermore, two opposite side edges of each of the two first solid sub-patterns 101 extending in the second direction Y are at least partially exposed from a respective one of the two first hollowed sub-patterns 201 (i.e., a respective first hollowed sub-pattern); in other words, an orthographic projection of the two first solid sub-patterns 101 on the wafer at least partially overlaps with an orthographic projection of the two first hollowed sub-patterns 201 on the wafer, and an orthographic projection of the two opposite side edges of each of the two first solid sub-patterns 101 extending in the second direction Y on the wafer falls within a range of an orthographic projection of the respective first hollowed sub-pattern 201 on the wafer.

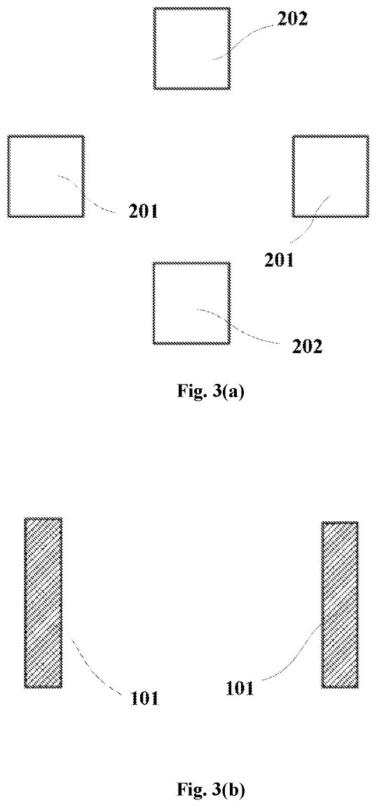

FIG. 3(a) and FIG. 3(b) show, in top views, portions of the overlay alignment mark as illustrated in FIG. 1(a) which are located respectively in the second layer 2 as a current layer and in the first layer 1 as a previous layer. Then, corresponding to the conditions as illustrated in FIG. 2(a) to FIG. 2(b), FIG. 3(a) shows in a top view a plane layout of the second pattern 20, which is located in the second layer 2 of the wafer, in the overlay alignment mark, and FIG. 3(b) shows also in a top view a plane layout of the first pattern 10, which is located in the first layer 1 of the wafer, in the overlay alignment mark. As such, for example, based on a combination of the specific layered arrangement of the overlay alignment mark as shown in the sectional views of FIG. 2(a) and FIG. 2(b) and the plane layouts of the portions of the overlay alignment mark which are located in various layer as shown in the top views of FIG. 3(a) and FIG. 3(b), then, in the first pattern 10 located in the first layer 1 below the second layer 2, the first solid sub-patterns 101 are at least partially observable from above through the respective first hollowed sub-patterns 201. Furthermore, while performing a single-pass (i.e., single-shot) SEM imaging on the second pattern of the second layer 2, the first pattern 10 (specifically, the two first solid sub-patterns 101) in the first layer 1 which is at least partially exposed through the two first hollowed sub-patterns 201 of the second pattern can also be imaged. As such, in the single-pass SEM image as obtained, respective portions thereof which are imaged from the two first hollowed sub-patterns 201, the two second hollowed sub-patterns 202, and the two first solid sub-patterns 101 respectively are for example referred to as “first hollowed sub-images”, “second hollowed sub-images” and “first solid sub-images”, respectively. Then, in the single-pass SEM image, side edges of a respective solid sub-image (e.g., outer side edge l₁ and inner side edge l₂, both of which extend in the second direction Y as illustrated in FIG. 1(a)) as imaged from side edges of each first solid sub-pattern 101, are at least partially exposed from and are thus observable through a respective first hollowed sub-image as imaged from a respective first hollowed sub-pattern 201 which overlaps with said first solid sub-pattern 101.

For convenience, the second layer 2 only formed with hollowed sub-patterns therein is also referred to as the current layer; and the first layer 1 located below the second layer 2 is also referred to as the previous layer.

Basic Embodiment of Overlay Alignment Mark

In exemplary embodiments, the first pattern 10 is formed in the first layer 1, such as the two first solid sub-patterns 101; the second pattern 20 is formed in the second layer 2, such as the two first hollowed sub-patterns 201 and the two second hollowed sub-patterns 202, as shown in the sectional views. The first layer 1 is for example a silicon substrate, a conductive layer or an insulating layer; and the second layer 2 is for example a conductive layer or an insulating layer. Moreover, the two first solid sub-patterns 101 are for example designed as solid patterns having strip-shaped sections, such as a column-shaped structure, a truncated cone-shaped structure or the like which is formed in the first layer 1 or projects from a surface of another material layer below the first layer 1; and the two first hollowed sub-patterns 201 and the two second hollowed sub-patterns 202 are for example groove structures recessed into the second layer 2.

By the settings on the basis of the aforementioned general technical concept, that is, the first solid sub-patterns 101 in the first layer 1 and the first hollowed sub-patterns 201 in the second layer 2 at least partially overlap with each other, such that respective two side edges of each of the two first solid sub-patterns 101 which are opposite to each other in the first direction X and extend in the second direction Y, are at least partially exposed from a respective one of the two first hollowed sub-patterns 201, then, substantially, the first solid sub-patterns 101 in the first layer 1 functioning as the previous layer are observable from above, at least partially through the first hollowed sub-patterns 201 in the second layer 2 functioning as the current layer; that is to say, while performing a SEM imaging on the second layer 2, the two first solid sub-patterns 101 in the first layer 1 which are at least partially exposed through the two first hollowed sub-patterns 201 in the second layer 2 can also be imaged. As such, in contrast to a solution in the relevant art where respective portions of an overlay alignment mark located respectively in various layers of the wafer are arranged such that their respective orthographic projections on the wafer are staggered with respect to each other (i.e. they fail to overlap with each other at all) and thus it is necessary to acquire SEM patterns layer by layer, then, in the solution of embodiments of the present disclosure, since the first solid sub-patterns 101 in the previous layer at least partially overlap with the first hollowed sub-patterns 201 in the current layer and thus are observable through the latter from above, then, portions of the overlay alignment mark located in different layers (i.e. the first pattern 10 and the second pattern 20) can be obtained simultaneously merely by acquiring once a single-pass SEM image of both the previous layer and the current layer which overlap at least partially with each other, so as to avoid moving the SEM apparatus for many times during a layer-by-layer acquisition of SEM images by scanning thereby and an interference thus caused on measurement of the overlay error as applied by a displacement of the SEM apparatus relative to specific locations of the wafer to be scanned by electron beam emitted from the SEM apparatus, then it is not necessary to adjust energy of the electron beam of the SEM apparatus for many times; and the overlay error between different layers of the wafer, e.g., the overlay error between the current layer and the previous layer (and more specifically, for example, a component of the overlay error for example in the first direction X), can be calculated based on the single-pass SEM image by acquiring the SEM image only once, simplifying steps of measuring the overlay error.

In an exemplary embodiment, as shown in FIG. 1(a), for example, each first solid sub-pattern 101 is designed to be in the form of a solid pattern having a strip-shaped section, and the two first solid sub-patterns 101 are designed such that they not only have central symmetry, to each other, about the first reference point O₁, but also have mirror symmetry to each other with respect to the first reference point O₁ (that is, the first reference point O₁ functions as a reference about which the two first solid sub-patterns 101 have central symmetry; and since the two first solid sub-patterns 101 are provided opposite to each other in the first direction X and extend in the second direction Y respectively, then an axis which is parallel to the second direction Y and passes through the first reference point O₁ functions as an axis with respect to which the two first solid sub-patterns 101 have mirror symmetry, i.e., for short, the first reference point O₁ also functions as a reference of mirror symmetry of the two first solid sub-patterns 101). Therefore, the first reference point O₁ is hereinafter referred to as a symmetrical center of the two first solid sub-patterns 101. And, by way of example, the first hollowed sub-patterns 201 and the second hollowed sub-patterns 202 are each designed to be in the form of through-hole having rectangular section, and one type of the two first hollowed sub-patterns 201 and the two second hollowed sub-patterns 202 (for example, the two second hollowed sub-patterns 202 as shown in the figure which do not overlap with the two first solid sub-patterns 101 at all) are designed to not only have central symmetry about the second reference point O₂, but also have mirror symmetry with respect to the second reference point O₂ (for example, the second reference point O₂ functions as a reference about which the two second hollowed sub-patterns 202 have central symmetry; and since the two second hollowed sub-patterns 202 are provided opposite to each other in the second direction Y, then an axis which is parallel to the first direction X and passes through the second reference point O₂ functions as an axis with respect to which the two second hollowed sub-patterns 202 have mirror symmetry, i.e., for short, the second reference point O₂ also functions as a reference of mirror symmetry of the two second hollowed sub-patterns 202). Therefore, the second reference point O₂ is hereinafter referred to as a symmetrical center of the two second hollowed sub-patterns 202. Furthermore, a coordinate value of the first reference point O₁ in the first direction X and a coordinate value of the second reference point O₂ in the first direction X are set such that a difference between these two coordinate values is expected to be a first constant.

Moreover, in an ideal condition, the first constant is for example set to be zero, that is, the difference between the coordinate value of the first reference point O₁ in the first direction X and the coordinate value of the second reference point O₂ in the first direction X is the first constant having a value of zero (that is, the coordinate value of the first reference point O₁ in the first direction X and the coordinate value of the second reference point O₂ in the first direction X should be equal to each other at this time).

As shown in FIG. 2(a) and FIG. 2(b), the first reference point O₁ and the second reference point O₂ are essentially respective projection points of two axes on the wafer both of which are respectively presented as the first axis and the second axis along the normal direction of the wafer in the sectional views of FIG. 2(a) and FIG. 2(b), and therefore these two reference points are each in the form of dot shape as illustrated in the top views of FIG. 1(a) and FIG. 1(b).

FIG. 1(b) shows a schematic top view of a typical example of the overlay alignment mark as described in FIG. 1(a). In a typical embodiment, for example as shown in FIG. 1(b), the coordinate value of the first reference point O₁ in the first direction X and the coordinate value of the second reference point O₂ in the first direction X are designed such that the difference therebetween is expected to be the first constant, and a coordinate value of the first reference point O₁ in the second direction Y and a coordinate value of the second reference point O₂ in the second direction Y are designed such that a difference therebetween is expected to be a second constant; and, in an ideal condition, the first constant is for example set to be zero, that is, the difference between the coordinate value of the first reference point O₁ in the first direction X and the coordinate value of the second reference point O₂ in the first direction X is the first constant having a value of zero (that is, the two coordinate values should be equal to each other at this time); and the second constant is set to be zero, that is, the difference between the coordinate value of the first reference point O₁ in the second direction Y and the coordinate value of the second reference point O₂ in the second direction Y is the second constant having a value of zero (i.e. the two coordinate values should be equal to each other at this time). That is to say, the first reference point O₁ and the second reference point O₂ are designed such that they are expected to coincide with each other ideally.

With such a specific setting, a deviation between the coordinate value of the first reference point O₁ (which functions as the symmetrical center of the two first solid sub-patterns 101) in the first direction X as practically measured and the coordinate value of the second reference point O₂ (which functions as the symmetrical center of the two second hollowed sub-patterns 202) in the first direction X can be simply calculated (the difference between the coordinate value of the symmetrical center O₁ of the two first solid sub-patterns 101 in the first direction X and the coordinate value of the symmetrical center O₂ of the two second hollowed sub-patterns 202 in the first direction X is supposed/expected in the design to be the first constant, for example zero), on the basis of the single-pass SEM image which is acquired for both the first layer 1 and the second layer 2 which overlap at least partially with each other, so as to obtain a component of the overlay error between the current layer and the previous layer for example in the first direction X.

Some Embodiments of Overlay Error Based on Overlay Alignment Mark

According to some embodiments of the present disclosure, based on the basic embodiment of the overlay alignment mark as described above, and furthermore, in a condition that the overlay alignment mark is formed in two layers of the wafer, and a difference between coordinate values of centers of respective portions of the overlay alignment mark in the two layers (for example, the symmetrical centers of respective sub-patterns (the solid sub-patterns or the hollowed sub-patterns) functioning as the first reference point O₁ and the second reference point O₂, as mentioned above, respectively) in one direction is a constant (typically, for example, the difference is zero, that is, these two coordinates values are equal to each other), then at least the deviation in such a direction (for example, the first direction X), in the overlay error between the two layers, can be calculated.

For example, the overlay error between different layers of the wafer, for example, the overlay error between the first layer 1 and the second layer 2, at least comprises one of following: a deviation between the first layer and the second layer in the first direction, which is defined by subtracting the first constant (e.g., zero as mentioned above) from a deviation between the first pattern 10 and the second pattern 20 in the first direction X (here the deviation between the first layer and the second layer in the first direction is a component of the overlay error in the first direction X, and is for example also referred to as an X-component deviation); and a deviation between the first layer and the second layer in the second direction, which is defined by subtracting the second constant from a deviation between the first pattern 10 and the second pattern 20 in the second direction Y (here the deviation between the first layer and the second layer in the second direction is a component of the overlay error in the second direction Y, and is for example also referred to as a Y-component deviation).

Specifically, by way of example, the deviation between the first pattern 10 and the second pattern 20 in the first direction X is for example directly defined as a difference between the coordinate value of the first reference point O₁ in the first direction X as practically measured and the coordinate value of the second reference point O₂ in the first direction X (the difference between the coordinate value of the first reference point O₁ in the first direction X and the coordinate value of the second reference point O₂ in the first direction X is supposed/expected in the design to be the first constant, for example zero). Additionally or alternatively, the deviation between the first pattern 10 and the second pattern 20 in the second direction Y is for example directly defined as a difference between the coordinate value of the first reference point O₁ in the second direction Y as practically measured and the coordinate value of the second reference point O₂ in the second direction Y (the difference between the coordinate value of the first reference point O₁ in the second direction Y and the coordinate value of the second reference point O₂ in the second direction Y is supposed/expected in the design to be the second constant, for example zero).

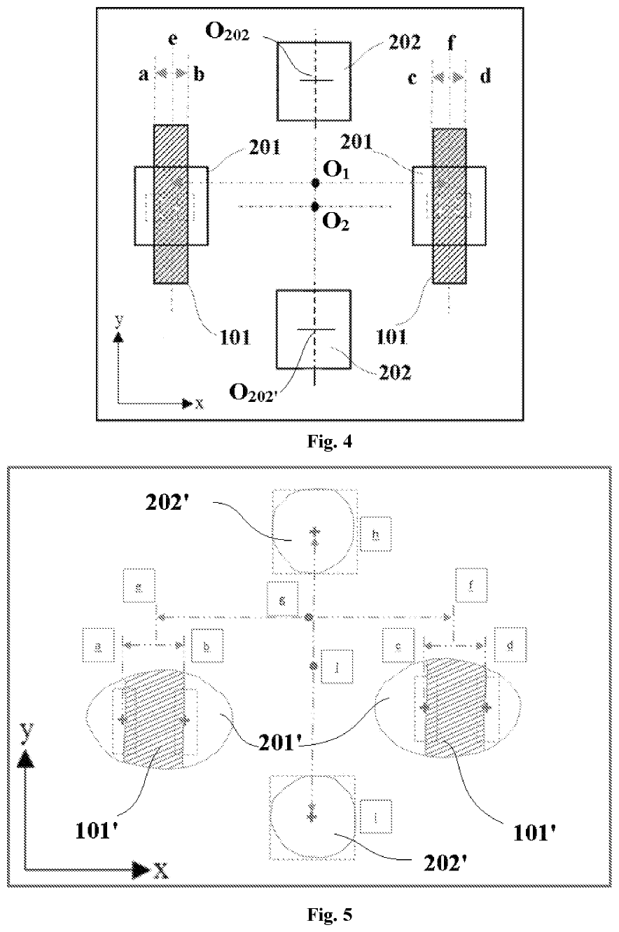

FIG. 4 schematically shows that an overlay error between two different layers are calculated depending on the overlay alignment mark as illustrated in FIG. 1(a), according to embodiments of the present disclosure. Thus, based on the arrangement of the overlay alignment mark as above, especially respective arrangements of the first pattern 10 and the second pattern 20 thereof, then in a condition that the overlay alignment mark is formed in two layers of the wafer, and a difference between coordinate values of centers of respective portions of the overlay alignment mark in the two layers (for example, symmetrical centers of respective sub-patterns functioning as the first reference point O₁ and the second reference point O₂, as mentioned above, respectively) in a same single direction (the first direction X, or the second direction Y) is a constant (for example, the first constant or the second constant), then the overlay error between different layers of the wafer (here, the two layers) for example has a first definition, e.g., as shown in FIG. 4, at least comprising: the deviation between the first pattern 10 and the second pattern 20 in the same single direction minus the first constant or the second constant in such direction; specifically, the difference between the coordinate value of the symmetrical center O₁ of the two first solid sub-patterns 101 for example in the first direction X and the coordinate value of the symmetrical center O₂ of the two second hollowed sub-patterns 202 for example in the first direction X (this difference is supposed/expected in the design to be the first constant, for example zero) directly functions as the deviation between the first pattern 10 and the second pattern 20 in such direction, and then the constant in such direction is subtracted from this deviation, with the result thus obtained being regarded as a component of the overlay error between the current layer and the previous layer, for example in such direction.

Based on the above basic embodiment of overlay alignment mark and the first definition of the deviation between two layers in the first direction X, in some embodiments, for example as shown in FIG. 4, in a condition that the two first solid sub-patterns 101 as shown in the figures are designed such that they not only have central symmetry, to each other, about the first reference point O₁, but also have mirror symmetry to each other with respect to the first reference point O₁, thereby the first reference point O₁ functions as the symmetrical center of the two first solid sub-patterns 101, then, the coordinate value of the first reference point O₁ in the first direction X is obtained, by extracting side edges of each first solid sub-pattern 101 to obtain centerline thereof extending in the second direction Y and in turn calculating a mean value of respective centerlines of the two first solid sub-patterns 101 extending in the second direction Y. For example, by performing edge extraction along the second direction Y for the respective first solid sub-images imaged from each first solid sub-pattern 101 in a single-pass SEM image, centerline of each of the two first solid sub-images extending in the second direction Y can be obtained, and then a mean value of coordinate values, in the first direction X, of the centerlines of the two first solid sub-images extending in the second direction Y is calculated.

In a specific embodiment, for example as shown in FIG. 4, the coordinate value of the first reference point O₁ in the first direction X is further defined as a mean value, in the first direction X, of the coordinate values of the respective centerlines, parallel to the second direction Y, of the two first solid sub-patterns 101, which not only have central symmetry to each other about the first reference point O₁ but also have mirror symmetry to each other with respect to the first reference point O₁.

In a more specific embodiment, for example, as shown in FIG. 4, the coordinate value of the centerline, parallel to the second direction Y, of each of the first solid sub-patterns 101 in the first direction X is further defined as the mean value of the coordinate values of two opposite side edges of each first solid sub-pattern 101 extending in the second direction Y in the first direction X.

In specific implementation, the edge extraction and coordinate calculation of each first solid sub-pattern 101 can be implemented by performing edge extraction in the single-pass SEM image based on edge extraction of the respective first solid sub-image which is imaged from each first solid sub-pattern 101 through the respective first hollowed sub-pattern 201 overlapping therewith. For example, as shown in FIG. 4, above all, on the SEM image, measurement points are set on the two first solid sub-images at four side edges thereof (two side edges for each first solid sub-image) extending substantially in the second direction and being presented in two pairs, in each pair of which respective two side edges therein are opposite to each other in the first direction; and then, as shown in FIG. 4, the coordinate values of the measurement points on the four side edges in the first direction (for example labeled by a, b, c, d as illustrated) are obtained by measurement; next, based on the aforementioned measurement points on the four side edges which are already extracted from the SEM image, coordinate values e, f of respective central locations of the two first solid sub-images in the direction X are calculated, depending on two equations of e=(a+b)/2, and f=(c+d)/2; finally, a mean value thereof (that is, (e+f)/2), i.e., a mean value of coordinate values of the centerlines of the two first solid sub-images extending in the second direction Y, in the first direction X can be calculated, which functions as the coordinate value of the first reference point O₁ in the first direction X. That is to say, the mean value, in the first direction X, of the coordinate values of two opposite side edges of each first solid sub-pattern 101 extending in the second direction Y is practically considered to be equal to the mean value of the coordinate values, in the first direction X, of the two opposite side edges of each first solid sub-image extending in the second direction Y in the single-pass SEM image.

In other words, when the component of the overlay error between the current layer and the previous layer in the first direction X is calculated based on the first definition, for example, by extracting two side edges of each first solid sub-pattern 101 extending in the second direction Y and calculating a mean value of coordinates thereof (for example, by extracting two side edges of each first solid sub-image extending in the second direction Y in the single-pass SEM image; and then, by calculating the mean value of the coordinate values thereof), thus the coordinate value, in the first direction X, of respective centerline of each first solid sub-pattern 101 extending in the second direction Y is obtained; and then, by calculating the mean value of coordinate values, in the first direction X, of respective centerlines of the two first solid sub-patterns 101 extending in the second direction Y, finally, the coordinate value of the symmetrical center O₁ of the two first solid sub-patterns 101 for example in the first direction X is obtained.

And, based on the above basic embodiment of overlay alignment mark and the first definition of the deviation between two layers in the first direction X, for example, in some embodiments, in a condition that the two second hollowed sub-patterns 202 for example as illustrated which do not overlap with the two first solid sub-patterns 101 at all are designed such that such that they not only have central symmetry, to each other, about the second reference point O₂, but also have mirror symmetry to each other with respect to the second reference point O₂ and thus the second reference point O₂ functions as the symmetrical center of the two second hollowed sub-patterns 202, then, geometrical centers O₂₀₂, O_{202′} of second hollowed sub-patterns 202 are obtained/found by graphical fitting of each of the second hollowed sub-patterns 202, and then respective coordinate values of the geometrical centers O₂₀₂, O_{202′} in the first direction X are acquired and in turn a mean value of the respective coordinate values of the geometrical centers O₂₀₂, O_{202′} in the first direction X is calculated (for example, by performing graphical fitting for the respective second hollowed sub-images as imaged from each second hollowed sub-pattern 202 in the single-pass SEM image to be a pattern (for example, a circle pattern or an ellipse pattern), and extracting the coordinate values, in the first direction X, of the geometric centers of respective patterns as obtained by the graphical fitting of the two second hollowed sub-images and in turn calculating the mean value of these coordinate values of the geometric centers), the coordinate value of the second reference point O₂ in the first direction X is thus obtained.

In a specific embodiment, for example, the coordinate value of the second reference point O₂ in the first direction X is further defined as: the mean value of the coordinate values, in the first direction X, of the geometric centers of the two second hollowed sub-patterns 202 which fail to overlap with the two first solid sub-patterns 101 at all and not only have central symmetry to each other about the second reference point O₂ but also have mirror symmetry to each other with respect to the second reference point O₂.

In a more specific embodiment, for example, the geometric center of each of the second hollowed sub-patterns 202 is further defined as a geometric center of the pattern (for example, the circle pattern or the ellipse pattern as illustrated) obtained by fitting from the second hollowed sub-pattern 202.

In the specific implementation, the graphical fitting of each of the second hollowed sub-patterns 202 and in turn calculation of coordinates of geometric centers of the patterns as obtained by graphical fitting, are implemented, by performing graphical fitting of the respective second hollowed sub-image as imaged from each of the second hollowed sub-patterns 202 and extracting geometric centers of fitted patterns, in the single-pass SEM image. By way of example, in a condition that each of the second hollowed sub-patterns 202 is designed in the form of a square section, typically, the respective second hollowed sub-image in the single-pass SEM image is fitted into a circle shape via a graphical fitting method; more specifically, for example, an outer circle which completely surrounds edges of the respective sub-image, and an inner circle which completely falls inside the edges of the respective sub-image, are above all constructed respectively, and the outer circle gradually shrinks inwards and the inner circle gradually expands outwards such that the outer circle and the inner circle gradually approach each other until both the outer circle and the inner circle get in a point-contact with (i.e., touch) edge(s) of the respective sub-image. At this time, a circle located in a closed loop region between the inner circle and the outer circle is further defined as a fitted circle. Or alternatively, for example, in a condition that each second hollowed sub-pattern 202 is designed in the form of a rectangular section, an ellipse can be fitted for the respective second hollowed sub-image in a similar way that the outer circle and the inner circle approach each other, one from outer side while the other from inner side of the respective second hollowed sub-image. The ellipse pattern is for example a positive ellipse (i.e., a standard ellipse rather than an inclined ellipse) having a major axis parallel to the first direction X and a minor axis parallel to the second direction Y; or the ellipse pattern is for example an inclined ellipse having a major axis which is inclined at a non-zero angle with respect to the first direction X and at another non-zero angle with respect to the second direction Y.

With the single-pass SEM image which is acquired for both the first layer 1 and the second layer 2 which overlap at least partially with each other, for example, and based on the first definition of the deviation in at least one direction in the overlay error as described above, for example by extracting side edges of each of the two solid sub-images as imaged from the two first solid sub-patterns 101 which are symmetrical with respect to the symmetrical center O₁ and calculating the mean value of coordinates of the side edges, and by performing graphical fitting for each of the two second hollowed sub-images as imaged from the two second hollowed sub-patterns 202 which are symmetrical with respect to the symmetrical center O₂, then it facilitates a calculation of a deviation between the coordinate value of the first reference point O₁ (which functions as the symmetrical center of the two first solid sub-patterns 101) in the first direction X as practically measured and the coordinate value of the second reference point O₂ (which functions as the symmetrical center of the two second hollowed features 202) in the first direction X (the difference between the coordinate value of the symmetrical center O₁ of the two first solid sub-patterns 101 in the first direction X and the coordinate value of the symmetrical center O₂ of the two second hollowed sub-patterns 202 in the first direction X is supposed/expected in the design to be the first constant, for example zero), thus, the component of the overlay error between the current layer and the previous layer, for example in the first direction X, is obtained in relatively simplified step(s).

In alternative or additional embodiments, by alternatively rotating the overlay alignment mark by 90 degrees, or by additionally setting another overlay alignment mark having the same patterns as the current overlay alignment mark but having its own orientation orthogonal to that of the current overlay alignment mark (for example, by providing the other overlay alignment mark having its patterns being the same as that of the current overlay alignment mark but its orientation being rotated 90 degrees as compared with that of the current overlay alignment mark, thus the first pattern 10 and the second pattern 20 of the other overlay alignment mark are specifically arranged such that, these patterns' respective arrangements in the first direction X and the second direction Y respectively are just opposite to those of pattern's in the overlay alignment mark as mentioned in the previous embodiments), then it also facilities that, based on the first definition as described above, the component of the overlay error between the current layer and the previous layer, for example in the second direction Y, is obtained in relatively simplified step(s), without repeating details of such embodiments herein any more.

FIG. 5 schematically shows that an overlay error between two different layers are obtained depending on existing patterns provided with sub-patterns in the arrangement as illustrated in FIG. 4, according to embodiments of the present disclosure, without forming a specialized/dedicated overlay alignment mark. In a further extended embodiment, in a specific application context (e.g., in a development process of devices or in a later error-checking process), overlay measurement marks may be easily lost, and thus cause a failure of a method for measuring overlay error in the relevant art. Then, by way of example as illustrated in FIG. 5, provided that for the existing pattern on the wafer (such as the geometric patterns of a chip itself), in a condition that at least two solid graphic features having respective strip-shaped sections are formed on the first layer 1 of the wafer, and at least four hollowed graphic features in the form of through-hole are formed on the second layer 2 of the wafer, and two solid graphic features provided opposite to each other in one of the first direction X and the second direction Y and being observable through respective hollowed graphic features not only have central symmetry but also have mirror symmetry to each other, about a midpoint of an imaginary line connecting between respective geometric centers of two hollowed graphic patterns provided opposite to each other in the other one of the first direction X and the second direction Y, then, the two solid graphic features function as the two first solid sub-patterns 101 and the two hollowed graphic features provided opposite to each other in the other one of the first direction X and the second direction Y function as the two second hollowed sub-patterns 202, and the first direction X and the second direction Y function as two mutually orthogonal directions. As such, based on aforementioned first definition of the deviation in the overlay error, in at least one direction, then a portion of graphic features of the existing patterns on both the previous layer and the current layer can be used as the overlay alignment mark, without forming a specialized/dedicated overlay alignment mark. Thus, the component of the overlay error between the current layer and the previous layer, for example in the first direction X, is obtained in relatively simplified step(s). And more specifically, for example, hollowed graphic features having respective strip-shaped section are for example a plurality of through-holes each of which is designed in the form of rectangular-shape or circular-shape. And more specifically, for example, each solid graphic feature having a strip-shaped section is a structure such as a column-shaped structure, a truncated cone-shaped structure or the like which is formed in the first layer 1 or projects from a surface of another material layer below the first layer 1.

By way of example, as shown in FIG. 5, above all, on the SEM image, measurement points are set on the two first solid sub-images at four side edges thereof (two side edges for each first solid sub-image) extending substantially in the second direction and being presented in two pairs, in each pair of which respective two side edges therein are opposite to each other in the first direction; and then, as shown in FIG. 4, the coordinate values of the measurement points on the four side edges in the first direction (for example labeled by a, b, c, d as illustrated) are obtained by measurement; next, based on the aforementioned measurement points on the four side edges which are already extracted from the SEM image, coordinate values e, f of respective central locations of the two first solid sub-images in the direction X are calculated, depending on two equations of e=(a+b)/2, and f=(c+d)/2; finally, a mean value thereof (that is, g=(e+f)/2), i.e., a mean value ‘g’ of coordinate values of the centerlines of the two first solid sub-images extending in the second direction Y, in the first direction can be calculated, which functions as the coordinate value of the first reference point O₁ in the first direction X. Moreover, in the single-pass SEM image, a graphical fitting is performed on the second hollowed sub-images imaged correspondingly from the second hollowed sub-patterns, so as to obtain the coordinate values, in the first direction X, (which are labeled by ‘h’, ‘i’, as illustrated) of the geometric centers of the two second hollowed sub-images as illustrated, and then a mean value of the coordinate values h, i, in the first direction X, of the geometric centers of the two second hollowed sub-images can be calculated, that is, j=(h+i)/2, then the mean value ‘j’ functions as the coordinate value of the second reference point O₂ in the first direction X. As such, the deviation between the first pattern and the second pattern in the first direction X is (g−j); and next, the first constant is subtracted from such deviation between said two patterns in the first direction X, with the result functioning as the deviation between the first layer and the second layer in the first direction X.

In a further extended embodiment, for example, assuming that several hollowed graphic features in the form of a plurality of through-holes arranged in an array are formed in the second layer 2 (i.e., the current layer) of the wafer, and several solid graphic features which have strip-shaped sections and are at least partially observable through the respective hollowed graphic features respectively are formed in the first layer 1 of the wafer (i.e., the previous layer); and furthermore, in a condition that the two solid graphic features in one of a row direction and a column direction of the plurality of through-holes are symmetrical to each other about a midpoint of an imaginary line connecting between respective geometric centers of two hollowed graphic patterns provided opposite to each other in the other one of the row direction and the column direction of the plurality of through-holes, then, the two solid graphic features function as the two first solid sub-patterns 101 of the first pattern 10 respectively, and the two hollowed graphic features which fail to overlap with the two first solid sub-patterns 101 at all then function as the two second hollowed sub-patterns 202 of the second pattern 20 respectively. And the two mutually orthogonal directions may function as the first direction X and the second direction Y as described above, respectively, e.g., the row direction and the column direction here. As such, based on the first definition of the deviation in at least one direction in the overlay error as described above, then a portion of graphic features of the existing pattern on both the previous layer and the current layer can be used as the overlay alignment mark, without additionally forming a specialized/dedicated overlay alignment mark. Thus, the component of the overlay error between the current layer and the previous layer, for example in the first direction X, is obtained in relatively simplified step(s).

In alternative or additional embodiments, for example, under the same assumptions, by alternatively rotating the overlay alignment mark by 90 degrees, or by additionally setting another overlay alignment mark having the same patterns as the current overlay alignment mark but having its own orientation orthogonal to that of the current overlay alignment mark (for example, by providing the other overlay alignment mark having its patterns being the same as that of the current overlay alignment mark but its orientation being rotated 90 degrees as compared with that of the current overlay alignment mark, thus the first pattern 10 and the second pattern 20 of the other overlay alignment mark are specifically arranged such that, these patterns' respective arrangements in the first direction X and the second direction Y respectively are just opposite to those of pattern's in the overlay alignment mark as mentioned in the previous embodiments (for example, in the other overlay alignment mark, the direction Y essentially functions as its first direction and the direction X functions as its second direction)), then it facilities that, a portion of graphic features of the existing pattern on both the previous layer and the current layer can be used as the overlay alignment mark, based on the first definition of the deviation in at least one direction in the overlay error as described above, without additionally forming a specialized/dedicated overlay alignment mark. Thus, the component of the overlay error between the current layer and the previous layer, for example in the second direction Y, is obtained in relatively simplified step(s), without repeating details of such embodiments herein any more.

Some Other Examples of Overlay Error Based on Overlay Alignment Mark

According to some embodiments of the present disclosure, based on the basic embodiment of the overlay alignment mark as described above, and furthermore, the overlay alignment mark is formed in at least two layers of the wafer. And for portions of the overlay alignment mark formed in different layers, for example, a difference between coordinate values of respective centers (e.g., respective symmetrical centers of respective sub-patterns thereof functioning as the first reference point O₁ and the second reference point O₂ as above, respectively) of a portion of the overlay alignment mark in a current layer (such portion merely comprising hollowed sub-patterns) and another portion of the overlay alignment mark in a previous layer below the current layer along one of the two orthogonal directions, is a constant; and a difference between coordinate values of respective centers (e.g., respective symmetrical centers of respective sub-patterns thereof functioning as the first reference point O₁ and the second reference point O₂ as above, or a third reference point O₃, respectively) of a portion of the overlay alignment mark in the current layer and another portion of the overlay alignment mark in the previous layer or a second previous layer (e.g., a third layer 3) which is different from the previous layer, below the current layer, in the other one of the two orthogonal directions is another constant. Then, in the overlay error, deviations between the current layer and the previous layer of the at least two layers in the two orthogonal directions can be calculated respectively; or alternatively, a deviation between the current layer and the previous layer in one of the two orthogonal directions and a deviation between the current layer and the third layer 3 different from the previous layer in the other one of the two orthogonal directions can be calculated respectively.

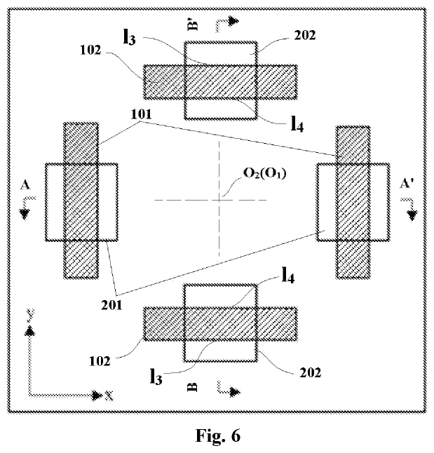

FIG. 6 shows a schematic top view of an overlay alignment mark according to other embodiments of the present disclosure.

By way of example, as shown in FIG. 6, in the overlay alignment mark as illustrated, the first pattern 10 further comprises two second solid sub-patterns 102 which are provided opposite to each other in the second direction Y and extend in the first direction X respectively, and two opposite side edges of each of the two second solid sub-patterns 102 extending in the first direction X are at least partially exposed from a respective one of the two second hollowed sub-patterns 202; in other words, an orthographic projection of the two second solid sub-patterns 102 on the wafer at least partially overlap with an orthographic projection of the two second hollowed sub-patterns 202 on the wafer respectively, and an orthographic projection of the two opposite side edges of each of the two second solid sub-patterns 102 extending in the first direction X on the wafer falls into the a range of an orthographic projection of the respective one of the two second hollowed sub-patterns 202 on the wafer, respectively.

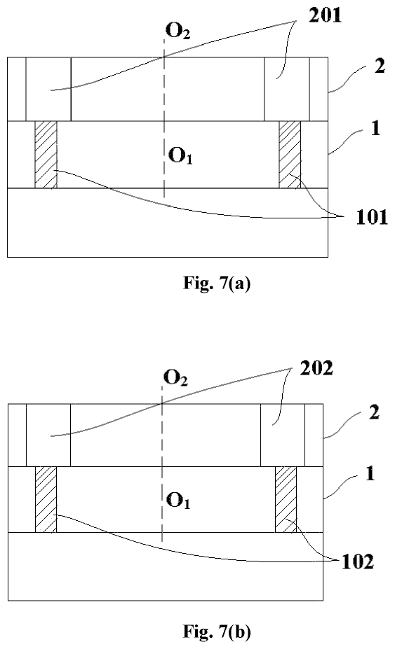

FIG. 7(a) and FIG. 7(b) illustrate sectional views which are cut along section lines A-A′ and B-B′ as shown in FIG. 6, respectively. More specifically, for example, a specific layered arrangement of the overlay alignment mark as shown in FIG. 6 can be shown schematically in FIG. 7(a) and FIG. 7(b), specifically showing the second pattern 20 (especially the first and second hollowed sub-patterns 201 and 202) located in the second layer 2 of the wafer and the first pattern 10 (especially the first solid sub-patterns 101 and the second solid sub-patterns 102) located in the first layer 1 immediately below the second layer 2.

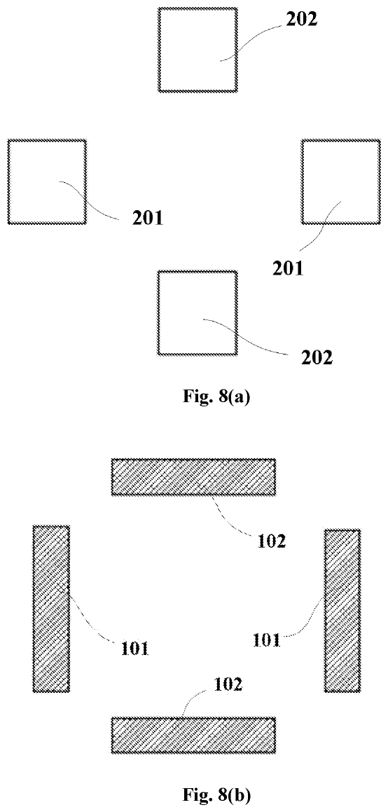

FIG. 8(a) and FIG. 8(b) illustrate, in top views, portions of the overlay alignment mark as illustrated in FIG. 6, in the second layer 2 functioning as the current layer and in the first layer 1 functioning as the previous layer, respectively. Then, corresponding to the illustrations of FIG. 7(a) and FIG. 7(b), FIG. 8(a) shows in a top view a plane layout of the second pattern 20 of the overlay alignment mark in the second layer 2 of the wafer, and FIG. 8(b) shows in a top view a plane layout of the first pattern 10 of the overlay alignment mark in the first layer 1 of the wafer. As such, by way of example, on the basis of a combination of the specific layered arrangement of the overlay alignment marks as shown in the sectional view of FIG.

7(a) and FIG. 7(b) and the plane layouts of the portions of the overlay alignment mark located in various layers as shown in the top views of FIG. 8(a) and FIG. 8(b), then, in the first pattern 10 located in the first layer 1 below the second layer 2, the first solid sub-patterns 101 are at least partially observable from above through the respective first hollowed sub-patterns 201, and the second solid sub-patterns 102 are at least partially observable from above through the respective second hollowed sub-patterns 202. Therefore, while performing a single-pass SEM imaging on the second pattern 20 in the second layer 2, the two second solid sub-patterns 102 of the first pattern 10 in the first layer 1 which are at least partially exposed through the second hollowed sub-patterns 202 of the second pattern 20 can also be imaged simultaneously. As such, in the single-pass SEM image as obtained, respective portions of the SEM which are imaged from the two second solid sub-patterns 102 respectively are for example referred to as “second solid sub-images”. Then, in the single-pass SEM image, side edges of a respective second solid sub-image (e.g., outer side edge l₃ and inner side edge l₄, both of which extend in the first direction X as illustrated in FIG. 6) as imaged from side edges of each second solid sub-pattern 102, are at least partially exposed from and are thus observable through a respective second hollowed sub-image as imaged from a respective second hollowed sub-pattern 202 which overlaps with said second solid sub-pattern 102. Moreover, for example, as illustrated in FIG. 7(a) and FIG. 7(b), the two first solid sub-patterns 101 and the two second solid sub-patterns 102 are for example designed as solid patterns having strip-shaped sections, such as a column-shaped structure, a truncated cone-shaped structure or the like which is formed in the first layer 1 or projects from a surface of other material layer(s) below the first layer 1.

In an exemplary embodiment, as shown in FIG. 8(b), for example, each of the second solid sub-patterns 102 is designed to be in the form of a solid pattern having a strip-shaped section, and the two second solid sub-patterns 102 are designed such that they not only have central symmetry, to each other, about the first reference point O₁, but also have mirror symmetry to each other with respect to the first reference point O₁ (that is, the first reference point O₁ functions as a reference about which the two second solid sub-patterns 102 have central symmetry; and since the two second solid sub-patterns 102 are provided opposite to each other in the second direction Y and extend in the first direction X respectively, then an axis which is parallel to the first direction X and passes through the first reference point O₁ functions as an axis with respect to which the two second solid sub-patterns 102 have mirror symmetry, i.e., for short, the first reference point O₁ also functions as a reference of mirror symmetry of the two second solid sub-patterns 102). Therefore, the first reference point O₁ is hereinafter referred to as a symmetrical center of the two second solid sub-patterns 102.

Furthermore, a coordinate value of the first reference point O₁ in the second direction Y and a coordinate value of the second reference point O₂ in the second direction Y are set such that a difference between these two coordinate values is expected to be a second constant. Moreover, in an ideal condition, the second constant is for example set to be zero, that is, the difference between the coordinate value of the first reference point O₁ in the second direction Y and the coordinate value of the second reference point O₂ in the second direction Y is the second constant having a value of zero (that is, the coordinate value of the first reference point O₁ in the second direction Y and the coordinate value of the second reference point O₂ in the second direction Y should be equal to each other at this time).

With such a specific setting, on the basis of the single-pass SEM image which is acquired for both the first layer 1 and the second layer 2 which overlap at least partially with each other, not only a deviation between the coordinate value of the first reference point O₁ (which functions as the symmetrical center of the two first solid sub-patterns 101) in the first direction X as practically measured and the coordinate value of the second reference point O₂ (which functions as the symmetrical center of the two second hollowed sub-patterns 202) in the first direction X can be simply calculated, from which deviation the first constant is in turn subtracted so as to define a component of the overlay error between the current layer and the previous layer for example in the first direction X (the difference between the coordinate value of the symmetrical center O₁ of the two first solid sub-patterns 101 in the first direction X and the coordinate value of the symmetrical center O₂ of the two second hollowed sub-patterns 202 in the first direction X is supposed/expected in the design to be the first constant, for example zero), but also a deviation between the coordinate value of the first reference point O₁ (which functions as the symmetrical center of the two second solid sub-patterns 102) in the second direction Y as practically measured and the coordinate value of the second reference point O₂ (which functions as the symmetrical center of the two second hollowed sub-patterns 202) in the second direction Y can be simply calculated, from which deviation the second constant is in turn subtracted so as to define a component of the overlay error between the current layer and the previous layer for example in the second direction Y (the difference between the coordinate value of the symmetrical center O₁ of the two second solid sub-patterns 102 in the second direction Y and the coordinate value of the symmetrical center O₂ of the two second hollowed sub-patterns 202 in the second direction Y is supposed/expected in the design to be the second constant, for example zero).

As such, as shown in the top view of FIG. 6, in view of the sectional views of the specific layered arrangement of the overlay alignment mark of FIG. 7(a) and FIG. 7(b) and the top views of the plane layout of the portions of the overlay alignment mark in various layers of FIG. 8(a) and FIG. 8(b), in some exemplary embodiments of the present disclosure provided as illustrated, in a condition that the overlay alignment mark is formed in two layers of the wafer, by way of example, an overlay error between different layers of the wafer, which is an overlay error between the first layer 1 and the second layer 2, as illustrated in FIG. 6 to FIG. 8(b), at the same time comprises following two items: a deviation between the first layer 1 and the second layer 2 in the first direction X, which is defined by subtracting the first constant from a deviation between the first pattern 10 and the second pattern 20 in the first direction X (the deviation between the first layer 1 and the second layer 2 in the first direction X is also referred to as a component of the overlay error in the first direction X, i.e., an X-component deviation); and a deviation between the first layer 1 and the second layer 2 in the second direction Y, which is defined by subtracting the second constant from a deviation between the first pattern 10 and the second pattern 20 in the second direction Y (the deviation between the first layer 1 and the second layer 2 in the second direction Y is also referred to as a component of the overlay error in the second direction Y, i.e., a Y-component deviation).

Specifically, by way of example, the deviation between the first pattern 10 and the second pattern 20 in the first direction X is for example directly defined as the difference between the coordinate value of the first reference point O₁ in the first direction X as practically measured and the coordinate value of the second reference point O₂ in the first direction X (the difference between the coordinate value of the first reference point O₁ in the first direction X and the coordinate value of the second reference point O₂ in the first direction X is supposed/expected in the design to be the first constant, for example zero). Moreover, the deviation between the first pattern 10 and the second pattern 20 in the second direction Y is for example directly defined as the difference between the coordinate value of the first reference point O₁ in the second direction Y as practically measured and the coordinate value of the second reference point O₂ in the second direction Y (the difference between the coordinate value of the first reference point O₁ in the second direction Y and the coordinate value of the second reference point O₂ in the second direction Y is supposed/expected in the design to be the second constant, for example zero).

In addition, assuming that there exist two layers overlapping with each other, such as a reference layer and an offset layer, then, in a condition that there are two strip-shaped patterns which are provided in the offset layer and are presented to be symmetric to each other (e.g., have mirror symmetry to each other) with respect to a point O in the reference layer, a Cartesian coordinate system is established, with the point O functioning as an origin of the coordinate system and an extension direction of the two strip-shaped patterns function as vertical direction Y of the Cartesian coordinate system; and in the direction X perpendicular to the direction Y of the Cartesian coordinate system, an initial coordinate value of a centerline of the left one of the two strip-shaped patterns extending in the direction Y of the Cartesian coordinate system is −d, while an initial coordinate value of a centerline of the right one of the two trip-shaped patterns extending in the direction Y of the Cartesian coordinate system is accordingly +d, then a distance between each of the two centerlines of the two patterns extending in the direction Y and the origin O is d, i.e., each of distances X1, X2, as illustrated, is d. Then, the offset layer is displaced, relative to the reference layer, and a component of the displacement in the direction X is Ad as illustrated; as such, in the direction X, the coordinate value of the centerline of the left one of the two strip-shaped patterns extending in the direction Y becomes −d+Δd accordingly, and the coordinate value of the centerline of the right one of the two-shaped patterns extending in the direction Y becomes d+Δd accordingly. Thereby, the distance X1 between the centerline of the left one of the two strip-shaped patterns extending in the direction Y and the origin O becomes [0−(−d+Δd)], and the distance X2 between the centerline of the right one of the two strip-shaped patterns extending in the direction Y and the origin O becomes [(d+Δd)−0], then, an absolute value of a difference value between the two distances is equal to 2Δd , i.e., |X1−X2=2Δd. Then, for two strip-shaped patterns symmetrically located on the offset layer with respect to the origin O on the reference layer and extending in one direction (the direction Y, or the direction X orthogonal to direction Y), the absolute value of the difference value between respective distances between respective centerlines of the two strip-shaped patterns in said one direction and the origin O can be considered to be equal to twice of the displacement of the offset layer relative to the reference layer in the other direction orthogonal to said one direction (the other direction referring to the direction X ,or the direction Y orthogonal to the direction X). Based on this principle, in a condition that the symmetrical center of the first pattern 10 of the first layer 1 (i.e., the first reference point O₁) coincides with the symmetrical center of the second pattern 20 of the second layer 2 (i.e., the second reference point O₂), or even slightly deviates from each other in advance (for example, at least one of the difference between the coordinate values of the two symmetrical centers in the first direction and the difference between the coordinate values of the two symmetrical centers in the second direction is constant), then a second definition of the overlay error between the first layer 1 and the second layer 2 of the wafer to be detected can be established.

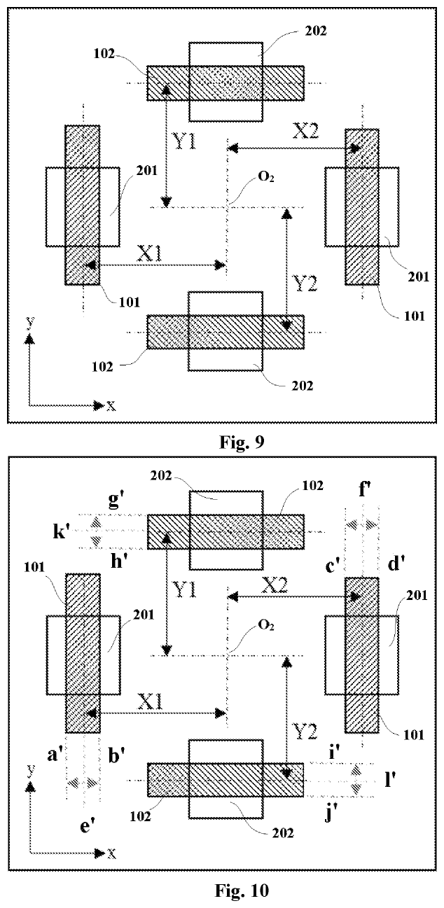

FIG. 9 schematically shows that, the overlay error between two different layers is obtained, with the overlay alignment mark as illustrated in FIG. 6, according to embodiments of the present disclosure. Thus, based on the arrangement of the overlay alignment mark as above, especially respective arrangements of the first pattern 10 and the second pattern 20 thereof, then in a condition that the overlay alignment mark is formed in two layers (i.e., the current layer and the previous layer) of the wafer, and a difference between coordinate values of centers of respective portions of the overlay alignment mark in the two layers (for example, the first reference point O₁ and the second reference point O₂, as above) in the first direction X is the first constant (the first constant is typically zero, for example) and a difference between coordinate values of centers of respective portions of the overlay alignment mark in the two layers (for example, the first reference point O₁ and the second reference point O₂, as above) in the second direction Y is also the second constant(the second constant is typically zero, for example), that is, the first reference point O₁ and the second reference point O₂ are slightly offset from each other in advance (for example, the difference between the two coordinate values in the first direction is a constant, and/or the difference between the two coordinate values in the second direction is a constant; furthermore, when the two constants in the first direction and in the second direction are all zero, respectively, the first reference point O₁ and the second reference point O₂ coincide with each other), then, the overlay error between the two layers for example has a second definition. Specifically, in the overlay error between the first layer 1 and the second layer 2, definitions of the deviations between the first layer 1 and the second layer 2 in the first direction and in the second direction respectively, for example as shown in FIG. 9, at least comprise: the deviation between the first pattern 10 and the second pattern 20 in the first direction X minus the first constant, the deviation between the first pattern 10 and the second pattern 20 in the first direction X being defined as ½ of a difference between distances between respective centerlines of the two first solid sub-patterns 101 parallel to the second direction Y and the second reference point O₂ (i.e., |X1−X2|/2), as illustrated); and the deviation between the first pattern 10 and the second pattern 20 in the second direction Y minus the second constant, the deviation between the first pattern 10 and the second pattern 20 in the second direction Y is defined as ½ of a difference between distances between respective centerlines of the two second solid sub-patterns 102 parallel to the first direction X and the second reference point O₂ (i.e., |Y1−Y2|/2), as illustrated).

FIG. 10 shows in more detail that, based on the overlay alignment mark as arranged in FIG. 9, the coordinate value of symmetrical center of the portion of overlay alignment mark as illustrated in FIG. 6 located in the first layer 1 is calculated. Based on the above basic embodiment of overlay alignment mark and the second definition of deviations between the two layers in the first direction X and in the second direction Y, respectively, in some embodiments, for example, as shown in FIG. 10, in a condition that the two first solid sub-patterns 101 are designed such that they not only have central symmetry to each other about the first reference point O₁ but also have mirror symmetry to each other with respect to the first reference point O₁, the two second solid sub-patterns 102 are designed such that they not only have central symmetry to each other about the first reference point O₁ but also have mirror symmetry to each other with respect to the first reference point O₁, and the first reference point O₁ and the second reference point O₂ are slightly offset from each other in advance (for example, at least one of the difference between the coordinate values of the two symmetrical centers in the first direction and the difference between the coordinate values of the two symmetrical centers in the second direction is constant; further, when both the difference between the coordinate values of the two symmetrical centers in the first direction and the difference between the coordinate values of the two symmetrical centers in the second direction are zero, i.e., two constants are zero, then, the first reference point O₁ and the second reference point O₂ coincide with each other); i.e., the coordinate values of the first reference point O₁ in the first direction X and the second reference point O₂ in the first direction X are designed such that the difference therebetween in the first direction X is the first constant (when the first constant is zero, these two coordinate values in the first direction are the same as each other) and the coordinate values of the first reference point O₁ in the second direction Y and the second reference point O₂ in the second direction Y are designed such that the difference therebetween in the second direction Y is the second constant (when the second constant is zero, these two coordinate values in the second direction Y are the same as each other), centerline of each first solid sub-pattern 101 extending in the second direction Y can be obtained by extracting side edges thereof, and centerline of each second solid sub-patterns 102 extending in the first direction X can be obtained by extracting side edges thereof.

In a specific embodiment, for example as shown in FIG. 10, a distance between respective centerline of each first solid sub-pattern 101 parallel to the second direction Y and the second reference point O₂ is defined as: an absolute value of a difference between the coordinate value, in the first direction X, of respective centerline of each of the first solid sub-patterns 101 parallel to the second direction Y and the coordinate value of the second reference point O₂ in the first direction X; and a distance between respective centerline of each second solid sub-pattern 102 parallel to the first direction X and the second reference point O₂ is defined as: an absolute value of a difference between the coordinate value, in the second direction Y, of respective centerline of each of the second solid sub-patterns 102 parallel to the first direction X and the coordinate value of the second reference point O₂ in the second direction Y.

In a more specific embodiment, for example as shown in FIG. 10, the coordinate value, in the direction X, of respective centerline of each of the first solid sub-patterns 101 parallel to the second direction Y is defined as a mean value of the coordinate values, in the first direction X, of respective two opposite side edges of each first solid sub-pattern 101 extending in the second direction Y, i.e., e′=(a′+b′)/2 and f′=(c′+d′)/2, as illustrated; and the coordinate value, in the second direction Y, of respective centerline of each of the second solid sub-patterns 102 parallel to first direction X is defined as a mean value of the coordinate values, in the second direction Y, of respective two opposite side edges of each of the second solid sub-patterns 102 extending in the first direction X, i.e., k′=(g′+h′)/2 and l′=(i′+j′)/2, as illustrated. In the specific implementation, by way of example, this is realized by performing edge extraction along the second direction Y for the respective first solid sub-images imaged from each of the first solid sub-patterns 101 in a single-pass SEM image so as to obtain centerlines of the two first solid sub-images extending in the second direction Y, and by performing edge extraction along the first direction X for the respective second solid sub-images imaged from each of the second solid patterns 102 in a single-pass SEM image so as to obtain centerlines of the two second solid sub-images extending in the first direction X.

Moreover, based on the above basic embodiment of overlay alignment mark and the second definition of the deviation between the two layers in the first direction X and the second direction Y, respectively, in order to calculate the coordinate values of the second reference point O₂ in the first direction X and in the second direction Y , i.e., to obtain the specific position of the second reference point O₂, then, in some embodiments, by way of example, as illustrated in FIG. 9, it is also required to design the overlay alignment mark that, each type of the first two first hollowed sub-patterns 201 and the two second hollowed sub-patterns 202 may be designed such that two hollowed sub-patterns in said type not only have central symmetry to each other about the second reference point O₂ but also have mirror symmetry to each other with respect to the second reference point O₂. Thereby, coordinate value of the second reference point O₂ in the first direction X may be obtained based on the two first hollowed sub-patterns 201, and coordinate value of the second reference point O₂ in the second direction Y may be obtained based on the two second hollowed sub-patterns 202.

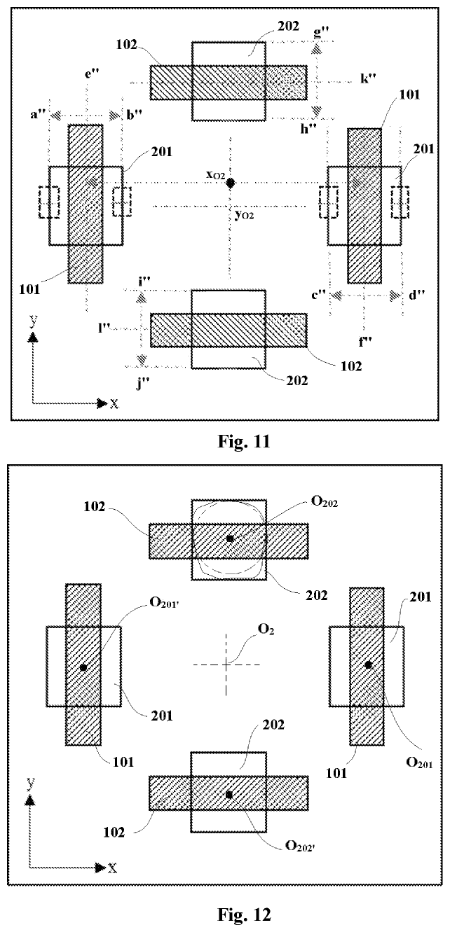

FIG. 11 shows in more detail a first way by which the coordinate values of the symmetrical center of the portion of the overlay alignment mark (as illustrated in FIG. 6) located in the second layer 2 can be obtained, based on the overlay alignment mark as arranged in FIG. 9. In some specific embodiments, by way of example, as shown in FIG. 11, centerline of each of the first hollowed sub-patterns 201 extending in the second direction Y can be obtained by extracting side edges thereof, and centerline of each of the second hollowed sub-patterns 202 extending in the first direction X can be obtained by extracting side edges thereof. By way of example, respective two opposite side edges of each of the first hollowed sub-patterns 201 which are opposite to each other in the first direction X all extend in the second direction Y, and the coordinate value of the second reference point O₂ in the first direction X is defined as: a mean value of coordinate values, in the first direction X, of respective centerlines of the two first hollowed sub-patterns 201 parallel to the second direction Y; and respective two opposite side edges of each of the second hollowed sub-patterns 202 which are opposite to each other in the second direction Y all extend in the first direction X, and the coordinate value of the second reference point O₂ in the second direction Y is defined as: a mean value of coordinate values, in the second direction Y, of respective centerlines of the two second hollowed sub-patterns 202 parallel to the first direction X.

More specifically, by way of example, as shown in FIG. 11, the coordinate value, in the direction X, of respective centerline of each of the first hollowed sub-patterns 201 parallel to the second direction Y is further defined as a mean value of the coordinate values, in the first direction X, of respective two opposite side edges of each of the first hollowed sub-patterns 201 extending in the second direction Y, i.e., e″=(a″+b″)/2 and f′=(c″+d″)/2, as illustrated; and the coordinate value, in the second direction Y, of respective centerline of each of the second hollowed sub-patterns 202 parallel to first direction X is defined as a mean value of the coordinate values, in the second direction Y, of respective two opposite side edges of each of the second hollowed sub-patterns 202 extending in the first direction X, i.e., k″=(g″+h″)/2 and l″=(i″+j″)/2, as illustrated. In other words, the coordinate value of the second reference point O₂ in the first direction X is defined as a half of a sum of mean values of coordinate values, in the first direction X, of respective two opposite side edges of the two first hollowed sub-patterns 201 extending in the second direction Y, i.e., x₀₂=(e″+f′)/2; and the coordinate value of the second reference point O₂ in the second direction Y is defined as a half of a sum of mean values of coordinate values, in the second direction Y, of respective two opposite side edges of the two second hollowed sub-patterns 202 extending in the first direction X, i.e., y₀₂=(k″+l″)/2.

In specific implementations, for example, this is specifically realized, by performing edge extraction along the second direction Y for the respective first hollowed sub-images imaged from each of the first hollowed sub-patterns 201 in a single-pass SEM image so as to obtain centerlines of the two first hollowed sub-images extending in the second direction Y, and then calculating a mean value of these two centerlines of the two first hollowed sub-images along the second direction Y; and by performing edge extraction along the first direction X for the respective second hollowed sub-images imaged from each of the second hollowed patterns 202 in a single-pass SEM image so as to obtain centerlines of the two second hollowed sub-images extending in the first direction X, and then calculating a mean value of these two centerlines of the two second hollowed sub-images along the first direction X.

FIG. 12 shows in more detail a second way by which the coordinate values of the symmetrical center of the portion of the overlay alignment mark (as illustrated in FIG. 6) located in the second layer 2 can be obtained, based on the overlay alignment mark as arranged in FIG. 9. In some other alternative specific embodiments, for example, as shown in FIG. 12, the rectangles indicated by reference numeral 202 refer to the two second hollowed sub-patterns 202 having respective ideal shapes as designed, and an irregular pattern as delimited within a solid line boundary and contained in a respective one of such rectangles is a practical profile of the respective second hollowed sub-pattern 202 produced by actual process, and a pattern as delimited within a dotted line boundary is a pattern profile which is obtained by fitting the respective second hollowed sub-pattern 202 produced by actual process. The coordinate values of the second reference point O₂ in both the first direction X and the second direction Y are obtained by a graph fitting method similar to that as mentioned above. As an example, the coordinate value of the second reference point O₂ in the first direction X is defined as a mean value of coordinate values of respective geometric centers O₂₀₁, O_{201′} of the two first hollowed sub-patterns 201 in the first direction X, or a mean value of coordinate values of respective geometric centers O₂₀₂, O_{202′} of the two second hollowed sub-patterns 202 in the first direction X; and the coordinate value of the second reference point O₂ in the second direction Y is defined as a mean value of coordinate values of respective geometric centers O₂₀₁, O_{201′} of the two first hollowed sub-patterns 201 in the second direction Y, or a mean value of coordinate values of respective geometric centers O₂₀₂, O_{202′} of the two second hollowed sub-patterns 202 in the second direction Y.

More specifically, for example, as shown in FIG. 12, the geometric center of each of the second hollowed sub-patterns 202 is further defined as the geometric center of a circle pattern or an ellipse pattern obtained by fitting from respective two second hollowed sub-patterns 202. In a specific implementation, this is for example realized, for respective first hollowed sub-image imaged from each of the first hollowed sub-patterns 201 and for respective second hollowed sub-image imaged from each of the second hollowed sub-patterns 202 in a single-pass SEM image, by graphical fitting and center extraction performed thereafter (for example, being fitted into a circle pattern or an ellipse pattern by graphical fitting; and then coordinate values, in the first direction X, of respective geometric centers O₂₀₁, O_{201′} of such patterns fitted respectively from the two first hollowed sub-images are extracted and a mean value of the coordinate values in the first direction X of the geometric centers O₂₀₁, O_{201′} is calculated so as to obtain the coordinate value of the second reference point O₂ in the first direction X; and coordinate values, in the second direction Y, of respective geometric centers O₂₀₂, O_{202′} of such patterns fitted respectively from the two second hollowed sub-images are extracted and a mean value of the coordinate values in the second direction Y of the geometric centers O₂₀₂, O_{202′} is calculated so as to obtain the coordinate value of the second reference point O₂ in the second direction Y).

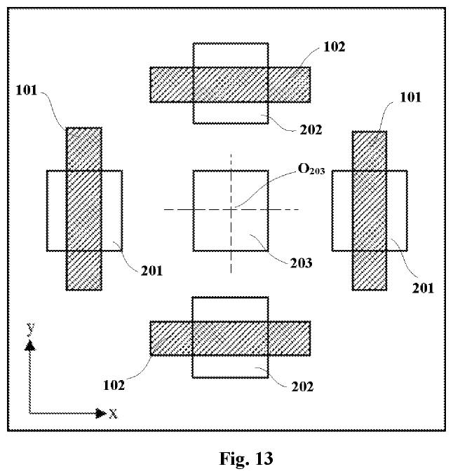

FIG. 13 shows in more detail a third way by which the coordinate values of the symmetrical center of the portion of the overlay alignment mark (as illustrated in FIG. 6) located in the second layer 2 can be obtained, based on the overlay alignment mark as arranged in FIG. 9. In some alternative specific embodiments, for example as shown in FIG. 13, by adding a central hollowed sub-pattern 203 to the second pattern 20, and a geometric center of the central sub-pattern 203 serves as not only a symmetrical center of the two first hollowed sub-patterns 201 but also a symmetrical center of the two second hollowed sub-patterns 202, i.e., the geometric center of the central sub-pattern 203 serves as the second reference point O₂. Thereby, the coordinates of the symmetrical center O₂₀₃ of the central hollowed sub-pattern 203 as added are the coordinates of the second reference point O₂. As an example, the second pattern 20 also comprises: a central hollowed sub-pattern 203, the central hollowed sub-pattern 203 is arranged centrally between the two first hollowed sub-patterns 201 and arranged centrally between the two second sub-patterns 202, with a geometric center of the central hollowed sub-pattern 203 functioning as the second reference point O₂.

More specifically, for example, as shown in FIG. 13, the center hollowed sub-pattern 203 is designed as a through-hole having a rectangular section. With this setting, for example, it is only required to measure the geometric center of the central hollowed sub-pattern 203 so as to obtain the coordinates of the second reference point O₂. For example, it is realized by graphical fitting of the central hollowed sub-pattern 203, and then calculating the geometric center of the fitted pattern. In a specific implementation, this is for example specifically realized in the following way: in a single-pass SEM image, a respective central hollowed sub-image imaged from the central hollowed sub-pattern 203 is fitted by graphical fitting, and then a geometric center of the fitted pattern is obtained. Thus, the coordinates of the second reference point O₂ are obtained in a simple way, avoiding the above indirect calculation.

According to some other exemplary embodiments of the present disclosure, based on the basic embodiment of the overlay alignment mark as described above, and furthermore, for a condition where the overlay alignment mark is formed in three layers of the wafer, the overlay error among the first layer 1, the second layer 2, and the third layer 3 can be measured.

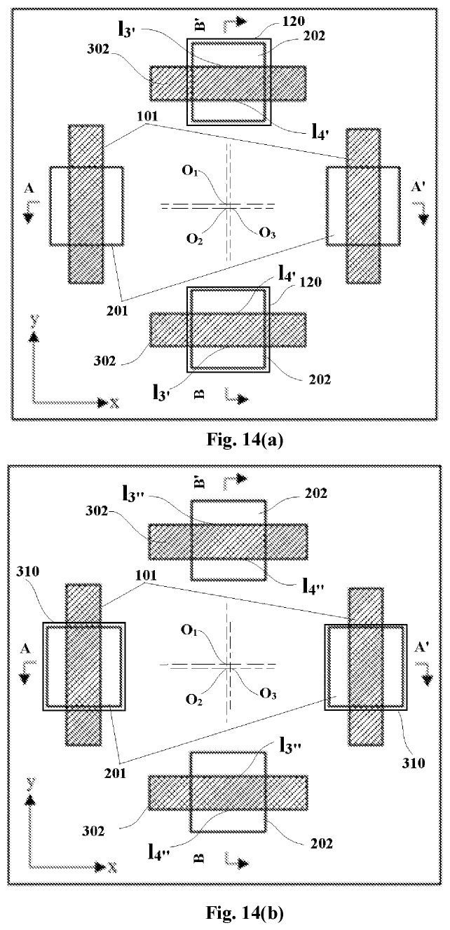

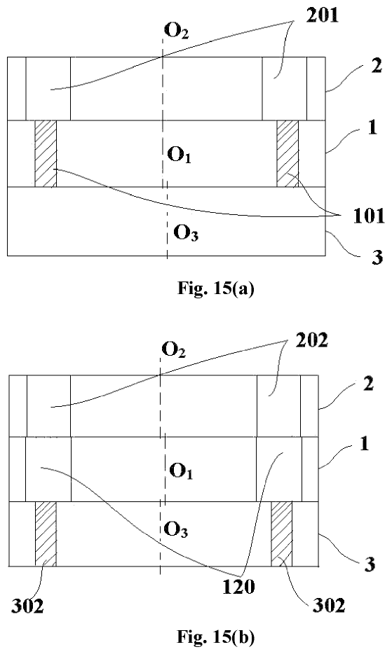

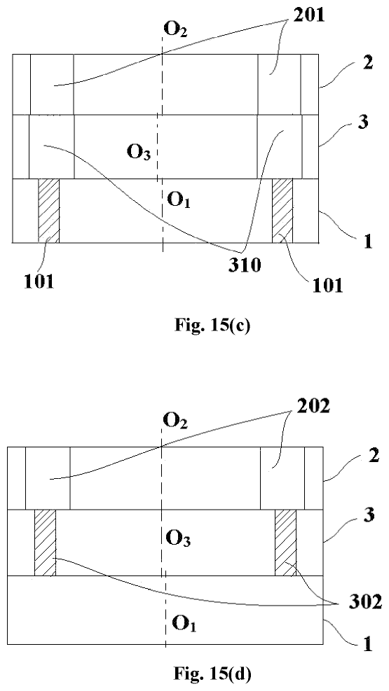

FIG. 14(a) and FIG. 14(b) show schematic top views of a first arrangement and a second arrangement of overlay alignment marks according to further embodiments of the present disclosure. In addition, FIG. 15(a) and FIG. 15(b) show sectional views cut along the section lines A-A′ and B-B′ in FIG. 14(a), respectively; and FIG. 15(c) and FIG. 15(d) show sectional views cut along the section lines A-A′ and B-B′ in FIG. 14(b), respectively.

As an example, as shown in FIG. 14(a) and FIG. 14(b), the overlay alignment mark further comprises: a third pattern 30 in a third layer 3 of the wafer, and the third layer 3 is located below the first layer 1 of the wafer (for example, as shown in FIG. 15(a) and FIG. 15(b), where the first layer 1 serves as a previous layer and the third layer 3 serves as a second previous layer), or the third layer 3 is located between the first layer 1 and the second layer 2 (for example, as shown in FIG. 15(c) and FIG. 15(d), where the third layer 3 serves as a previous layer, and the first layer 1 serves as a second previous layer), and the third pattern 30 comprises two second solid sub-patterns 302 which are provided opposite to each other in the second direction Y and extend in the first direction X, respectively and two opposite side edges of each of the two second solid sub-patterns 302 extending in the first direction X are at least partially exposed from a respective one of the two second hollowed sub-patterns 202. In other words, an orthographic projection of the two second solid sub-patterns 302 on the wafer at least partially overlaps with an orthographic projection of the two second hollowed sub-patterns 202 on the wafer, and an orthographic projection of two opposite side edges of each of the two second solid sub-patterns 302 extending in the first direction X on the wafer falls within a range of an orthographic projection of the respective one of the two second hollowed sub-patterns 202 on the wafer.

More specifically, for example, in a condition that the overlay alignment mark comprises a third pattern 30 located in the third layer 3, the specific layered arrangement of the example of the overlay alignment mark shown in FIG. 14(a) is schematically illustrated in FIG. 15(a) to FIG. 15(b), showing the second pattern 20 (especially the first hollowed sub-patterns 201 and the second hollowed sub-patterns 202) of the overlay alignment mark located in the second layer 2 of the wafer, the first pattern 10 (especially the first solid sub-patterns 101) of the overlay alignment mark located in the first layer 1 immediately below the second layer 2 of the wafer, and the third pattern 30 (especially the second solid sub-patterns 302) of the overlay alignment mark located in the third layer 3 immediately below the first layer 1 of the wafer; Or alternatively, for example, in another condition that the overlay alignment mark comprises a third pattern 30 located in the third layer 3, the specific layered arrangement of the example of the overlay alignment mark shown in FIG. 14(b) is schematically illustrated in FIG. 15(c) to FIG. 15(d), showing the second pattern 20 (especially the first hollowed sub-patterns 201 and the second hollowed sub-patterns 202) of the overlay alignment mark located in the second layer 2 of the wafer, the third pattern 30 (especially the second solid sub-patterns 302) of the overlay alignment mark located in the third layer 3 immediately below the second layer 2 of the wafer, and the first pattern 10 (especially the first solid sub-patterns 101) of the overlay alignment mark located in the first layer 1 immediately below the third layer 3 of the wafer.

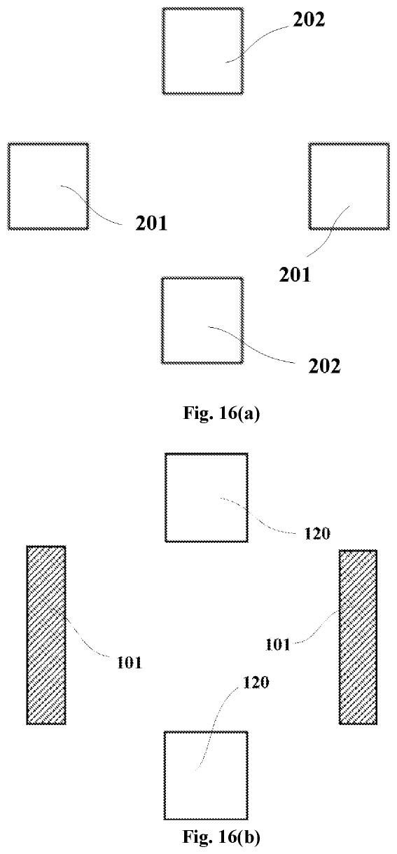

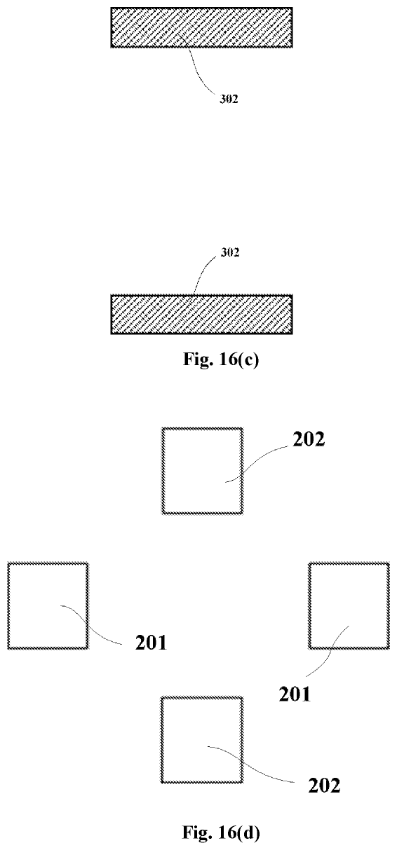

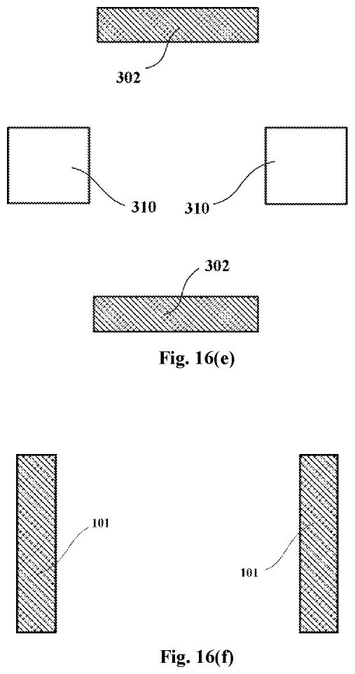

FIG. 16(a) to FIG. 16(c) show, in top views, portions of the overlay alignment mark as illustrated in FIG. 14(a) which are located in the second layer 2 (functioning as the current layer), in the first layer 1 (functioning as the previous layer), and in the third layer 3 (functioning as the second previous layer), respectively; FIG. 16(d) to FIG. 16(f) show, in top views, portions of the overlay alignment mark as illustrated in FIG. 14(b) which are located in the second layer 2 (functioning as the current layer), in the third layer 3 (functioning as the previous layer), and in the first layer 1 (functioning as the second previous layer), respectively.

Next, corresponding to one condition of above conditions that the overlay alignment mark as shown in FIG. 15(a) to FIG. 15(b) comprises the third pattern 30 located in the third layer 3, FIG. 16(a) shows, in top view, a plane layout of the second pattern 20 of the overlay alignment mark in the second layer 2 of the wafer, and FIG. 16(b) shows, in top view, a plane layout of the first pattern 10 of the overlay alignment mark in the first layer 1 of the wafer, and FIG. 16(c) shows, in top view, a plane layout of the third pattern 30 of the overlay alignment mark in the third layer 3 of the wafer. In particular, by way of example, as shown in FIG. 15(b) in view of FIG. 16(b), in a condition that the third layer 3 is located below the first layer 1, the first pattern 10 further comprises two third hollowed sub-patterns 120 provided opposite to each other in the second direction Y, and the two third hollowed sub-patterns 120 at least partially overlap with the two second hollowed sub-patterns 202 respectively, and two opposite side edges of each of the two second solid sub-patterns 302 extending in the first direction X are at least partially exposed from a respective third hollowed sub-pattern 120 and a respective second hollowed sub-pattern 202. In other words, an orthographic projection of the two second solid sub-patterns 302 on the wafer at least partially overlaps with an orthographic projection of the two third hollowed sub-patterns 120 on the wafer and an orthographic projection of the two second hollowed sub-patterns 202 on the wafer, respectively, and an orthographic projection of two opposite side edges of each of the two second solid sub-patterns 302 extending in the first direction X on the wafer falls within a range of an orthographic projection of the respective one of the two third hollowed sub-patterns 120 on the wafer and falls within a range of an orthographic projection of the respective one of the two second hollowed sub-patterns 202 on the wafer. By way of example, corresponding to the one condition as illustrated in FIG. 15(a) to FIG. 15(b) and FIG. 16(a) to FIG. 16(c), each of the third hollowed sub-patterns 120 is designed in the form of a through-hole having a rectangular section.

As such, by way of example, on the basis of a combination of the specific layered arrangement of the overlay alignment marks as shown in the sectional view of FIG. 15(a) and FIG. 15(b) with the plane layouts of the portions of the overlay alignment mark located in various layers as shown in the top views of FIG. 16(a) to FIG. 16(c), then, in the first pattern 10 located in the first layer 1 below the second layer 2, the first solid sub-patterns 101 are at least partially observable from above through the respective first hollowed sub-patterns 201; and in the third pattern 30 located in the third layer 3 below the first layer 1, the second solid sub-patterns 302 are at least partially observable from above through the respective third hollowed sub-patterns 120 and the respective second hollowed sub-patterns 202. Therefore, while performing a single-pass SEM imaging on the second pattern 20 in the second layer 2, the two first solid sub-patterns 101 of the first pattern 10 in the first layer 1 which are at least partially exposed through the first hollowed sub-patterns 201 of the second pattern 20 can also be imaged simultaneously, and the two second solid sub-patterns 302 of the third pattern 30 in the third layer 3 which are at least partially exposed through the third hollowed sub-patterns 120 of the first pattern 10 and the second hollowed sub-patterns 202 of the second pattern 20 can also be imaged simultaneously. As such, in the single-pass SEM image as obtained, respective portions of the SEM image which are imaged from the two second solid sub-patterns 302 respectively are for example referred to as “second solid sub-images”. Then, in the single-pass SEM image, side edges of a respective second solid sub-image (e.g., outer side edge l_{3′} and inner side edge l_{4′}, both of which extend in the first direction X as illustrated in FIG. 14(a)) as imaged from side edges of each of the second solid sub-patterns 302, are at least partially exposed from and are thus observable through a respective third hollowed sub-image as imaged from a respective third hollowed sub-pattern 120 and a respective second hollowed sub-image as imaged from a respective second hollowed sub-pattern 202, both of the respective third hollowed sub-pattern 120 and the respective second hollowed sub-pattern 202 overlapping with said second solid sub-pattern 302. Moreover, for example, as illustrated in FIG. 15(a) and FIG. 15(b), the two first solid sub-patterns 101 and the two second solid sub-patterns 302 are for example designed as solid patterns having strip-shaped sections, such as a column-shaped structure, a truncated cone-shaped structure or the like which is formed in the first layer 1 and in the third layer 3, or projects from a surface of other material layer(s) below the first layer 1 and below the third layer 3.

Or alternatively, next, corresponding to another condition of above conditions that the overlay alignment mark as shown in FIG. 15(c) to FIG. 15(d) comprises the third pattern 30 located in the third layer 3, FIG. 16(d) shows, in top view, a plane layout of the second pattern 20 of the overlay alignment mark in the second layer 2 of the wafer, and FIG. 16(e) shows, in top view, a plane layout of the third pattern 30 of the overlay alignment mark in the third layer 3 of the wafer, and FIG. 16(f) shows, in top view, a plane layout of the first pattern 10 of the overlay alignment mark in the first layer 1 of the wafer. In particular, by way of example, as shown in FIG. 15(c) in view of FIG. 16(e), in a condition that the third layer 3 is located between the first layer 1 and the second layer 2, the third pattern 30 further comprises two third hollowed sub-patterns 310 provided opposite to each other in the first direction X, and the two third hollowed sub-patterns 310 at least partially overlap with the two first hollowed sub-patterns 201 respectively, two opposite side edges of each of the two first solid sub-patterns 101 extending in the second direction Y are at least partially exposed from a respective third hollowed sub-pattern 310 and in turn a respective first hollowed sub-pattern 201, and two opposite side edges of each of the two second solid sub-patterns 302 extending in the first direction X are at least partially exposed from a respective second hollowed sub-pattern 202. In other words, an orthographic projection of the two first solid sub-patterns 101 on the wafer at least partially overlaps with an orthographic projection of the two third hollowed sub-patterns 310 on the wafer and an orthographic projection of the two first hollowed sub-patterns 201 on the wafer, respectively, and an orthographic projection of two opposite side edges of each of the two first solid sub-patterns 101 extending in the second direction Y on the wafer falls within a range of an orthographic projection of the respective one of the two third hollowed sub-patterns 310 on the wafer and falls within a range of an orthographic projection of the respective one of the two first hollowed sub-patterns 201 on the wafer; and an orthographic projection of the two second solid sub-patterns 302 on the wafer at least partially overlaps with an orthographic projection of the two second hollowed sub-patterns 202 on the wafer, and an orthographic projection of two opposite side edges of each of the two second solid sub-patterns 302 extending in the first direction X on the wafer falls within a range of an orthographic projection of the respective one of the two second hollowed sub-patterns 202 on the wafer. By way of example, corresponding to the another condition as illustrated in FIG. 15(c) to FIG. 15(d) and FIG. 16(d) to FIG. 16(f), each third hollowed sub-pattern 310 is designed in the form of a through-hole having a rectangular section.

As such, by way of example, on the basis of a combination of the specific layered arrangement of the overlay alignment marks as shown in the sectional view of FIG. 15(c) and FIG. 15(d) with the plane layouts of the portions of the overlay alignment mark located in various layers as shown in the top views of FIG. 16(d) to FIG. 16(f), then, in the third pattern 30 located in the third layer 3 below the second layer 2, the second solid sub-patterns 302 are at least partially observable from above through the respective second hollowed sub-patterns 202; and in the first pattern 10 located in the first layer 1 below the third layer 3, the first solid sub-patterns 101 are at least partially observable from above through the respective third hollowed sub-patterns 310 and the respective first hollowed sub-patterns 201. Therefore, while performing a single-pass SEM imaging on the second pattern 20 in the second layer 2, the two second solid sub-patterns 302 of the third pattern 30 in the third layer 3 which are at least partially exposed through the second hollowed sub-patterns 202 of the second pattern 20 can also be imaged simultaneously, and the two first solid sub-patterns 101 of the first pattern 10 in the first layer 1 which are at least partially exposed through the third hollowed sub-patterns 310 of the third pattern 30 and the first hollowed sub-patterns 201 of the second pattern 20 can also be imaged simultaneously. As such, in the single-pass SEM image as obtained, respective portions of the SEM image which are imaged from the two second solid sub-patterns 302 respectively are for example referred to as “second solid sub-images”. Then, in the single-pass SEM image, side edges of a respective second solid sub-image 302 (e.g., outer side edge l_{3″} and inner side edge l_{4″}, both of which extend in the first direction X as illustrated in FIG. 14(b)) as imaged from side edges of each second solid sub-pattern 302, are at least partially exposed from and are thus observable through a respective second hollowed sub-image as imaged from a respective second hollowed sub-pattern 202, the respective second hollowed sub-pattern 202 overlapping with said second solid sub-pattern 302. Moreover, for example, as illustrated in FIG. 15(c) and FIG. 15(d), the two first solid sub-patterns 101 and the two second solid sub-patterns 302 are for example designed as solid patterns having strip-shaped sections, such as a column-shaped structure, a truncated cone-shaped structure or the like which is formed in the first layer 1 and in the third layer 3, or projects from a surface of other material layer(s) below the first layer 1 and below the third layer 3.

Furthermore, in an exemplary embodiment, as shown in FIG. 16(c) or FIG. 16(e), for example, each second solid sub-pattern 302 is designed to be in the form of a solid pattern having a strip-shaped section, and the two second solid sub-patterns 302 are designed such that they not only have central symmetry, to each other, about the third reference point O₃, but also have mirror symmetry to each other with respect to the third reference point O₃ (that is, the third reference point O₃ functions as a reference about which the two second solid sub-patterns 302 have central symmetry; and since the two second solid sub-patterns 302 are provided opposite to each other in the second direction Y and extend in the first direction X respectively, then an axis which is parallel to the first direction X and passes through the third reference point O₃ functions as an axis with respect to which the two second solid sub-patterns 302 have mirror symmetry, i.e., for short, the third reference point O₃ also functions as a reference of mirror symmetry of the two second solid sub-patterns 302). Therefore, the third reference point O₃ is hereinafter referred to as a symmetrical center of the two second solid sub-patterns 302. Furthermore, a coordinate value of the third reference point O₃ in the second direction Y and a coordinate value of the second reference point O₂ in the second direction Y are set such that a difference between these two coordinate values is a second constant. Moreover, in an ideal condition, the second constant is for example set to be zero, that is, the difference between the coordinate value of the third reference point O₃ in the second direction Y and the coordinate value of the second reference point O₂ in the second direction Y is the second constant having a value of zero (that is, the coordinate value of the third reference point O₃ in the second direction Y and the coordinate value of the second reference point O₂ in the second direction Y should be equal to each other at this time).

As shown in FIG. 15(a) to FIG. 15(d), the first reference point O₁, the second reference point O₂ and the third reference point O₃ are essentially respective projection points of three axes on the wafer all of which are respectively presented as the first axis, the second axis and the third axis along the normal direction of the wafer in the sectional views of FIG. 15(a) to FIG. 15(d), and therefore these three reference points are each in the form of dot shape as illustrated in the top views of FIG. 14(a) and FIG. 14(b).

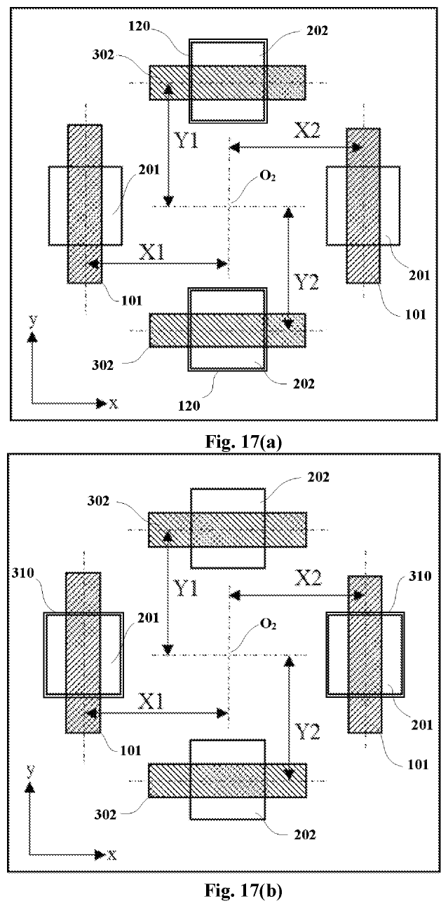

With such a specific setting, on the basis of the single-pass SEM image which is acquired for the first layer 1, the second layer 2 and the third layer 3 which overlap at least partially with each other or one another, respective coordinate values of the first reference point O₁, the second reference point O₂, and the third reference point O₃ respectively in various layers can be simply calculated, and the overlay error among the first layer 1, the second layer 2, and the third layer 3 can be calculated, comprising an overlay error between the first layer 1 and the second layer 2, and an overlay error between the third layer 3 and the second layer 2. Therefore, for a condition where the overlay alignment mark is formed in three layers of the wafer, by way of example, the overlay error between different layers of the wafer, as illustrated in FIG. 14(a) to FIG. 16(f), i.e., the overlay error among the first layer 1, the second layer 2, and the third layer 3, for example comprises: an overlay error between the first layer 1 and the second layer 2, and an overlay error between the third layer 3 and the second layer 2. In turn, the overlay error between the first layer 1 and the second layer 2 for example at least comprises: a deviation between the first layer 1 and the second layer 2 in the first direction X, which is defined by subtracting the first constant from a deviation between the first pattern 10 and the second pattern 20 in the first direction X. And the overlay error between the third layer 3 and the second layer 2 for example at least comprises: a deviation between the third layer 3 and the second layer 2 in the second direction Y, which is defined by subtracting the second constant from a deviation between the third pattern 3 and the second pattern 2 in the second direction Y. For example, as illustrated in FIG. 17(a) and FIG. 17(b), the overlay error between the first layer 1 and the second layer 2 at least comprises: the deviation between the first pattern 10 and the second pattern 20 in the first direction X minus the first constant; and the overlay error between the third layer 3 and the second layer 2 at least comprises: the deviation between the third pattern 30 and the second pattern 20 in the second direction Y minus the second constant.

Specifically, by way of example, the coordinate values of the second reference point O₂ of the second pattern 20 in the second layer 2 in the first direction X and the second direction Y, the coordinate value of the first reference point O₁ of the first pattern 10 in the first layer 1 in the first direction X, and the coordinate value of the third reference point O₃ of the third pattern 30 in the third layer 3 in the second direction Y can be obtained based on the single-pass SEM image. And the overlay error between these layers is thereby calculated, for example, at least comprising: the deviation between the first pattern 10 and the second pattern 20 in the first direction X minus the first constant; and the deviation between the third pattern 30 and the second pattern 20 in the second direction Y minus the second constant.

And as mentioned above, similar to the second definition of the overlay error between the first layer 1 and the second layer 2 of the wafer to be detected, which is established based on the overlay alignment mark between two layers as above, a definition of overlay error among the first layer 1, the second layer 2 and the third layer 3 of the wafer to be detected can be established for the overlay alignment mark among the three layers.

FIG. 17(a) schematically shows that, the overlay error among three different layers is obtained, with the overlay alignment mark as illustrated in FIG. 14(a), according to embodiments of the present disclosure; FIG. 17(b) schematically shows that, the overlay error among three different layers is obtained, with the overlay alignment mark as illustrated in FIG. 14(b), according to embodiments of the present disclosure. Thus, based on the arrangement of the overlay alignment mark as above, especially respective arrangements of the first pattern 10, the second pattern 20 and the third pattern 30 thereof, then in a condition that the overlay alignment mark is formed in three layers (i.e., the current layer, the previous layer and the second previous layer) of the wafer, and as illustrated in FIG. 15(a) an FIG. 15(b), a difference between a coordinate value of a center of the second pattern 20 in the second layer 2 (e.g., the aforementioned second reference point O₂) and a coordinate value of a center of the first pattern 10 in the first layer (e.g., the aforementioned first reference point O₁) of the overlay alignment mark in the first direction X is the first constant (these two coordinate values are equal to each other when the first constant is zero) and a difference between a coordinate value of the center of the second pattern 20 in the second layer 2 (e.g., the aforementioned second reference point O₂) and a coordinate value of a center of the third pattern 30 in the third layer 3 (e.g., the aforementioned third reference point O₃) of the overlay alignment mark in the second direction Y is the second constant (these two coordinate values are equal to each other when the second constant is zero), then, the overlay error among the three layers, for example as illustrated in FIG. 17(a) and FIG. 17(b), can be defined such that it at least comprises: the deviation between the first pattern 10 and the second pattern 20 in the first direction X minus the first constant, the deviation between the first pattern 10 and the second pattern 20 in the first direction X being defined as ½ of a difference between distances between respective centerlines of the two first solid sub-patterns 101 parallel to the second direction Y and the second reference point O₂ (that is to say, |X1−X2|/2), as illustrated in FIG. 17(a) and FIG. 17(b)); and the deviation between the third pattern 30 and the second pattern 20 in the second direction Y minus the second constant, the deviation between the third pattern 30 and the second pattern 20 in the second direction Y is defined as ½ of a difference between distances between respective centerlines of the two second solid sub-patterns 302 parallel to the first direction X and the second reference point O₂ (that is to say, |Y1−Y2|/2), as illustrated in FIG. 17(a) and FIG. 17(b)).

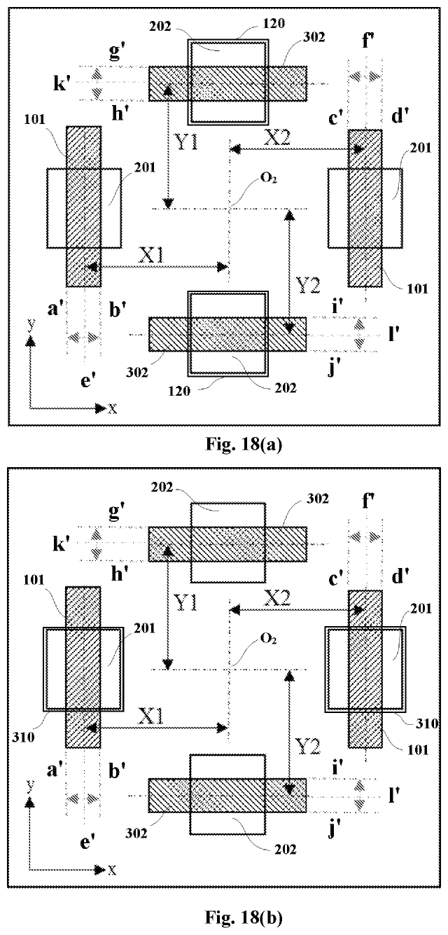

FIG. 18(a) shows in more detail that, based on the overlay alignment mark as arranged in FIG. 17(a), the coordinate values of symmetrical centers of portions of overlay alignment mark located in the first layer 1 and in the third layer 3 respectively as illustrated in FIG. 14(a) are calculated; and FIG. 18(b) shows in more detail that, based on the overlay alignment mark as arranged in FIG. 17(b), the coordinate values of symmetrical centers of portions of overlay alignment mark located in the first layer 1 and in the third layer 3 respectively as illustrated in FIG. 14(b) are calculated. Based on the embodiments of the overlay alignment mark among the three layers and the definition of deviations among the three layers in the first direction X and in the second direction Y, respectively, as described above, then, in some embodiments, for example, as shown in FIG. 18(a) and FIG. 18(b), since the two first solid sub-patterns 101 are designed such that they not only have central symmetry to each other about the first reference point O₁ but also have mirror symmetry to each other with respect to the first reference point O₁, and the two second solid sub-patterns 302 are designed such that they not only have central symmetry to each other about the third reference point O₃ but also have mirror symmetry to each other with respect to the third reference point O₃, and moreover, the coordinate values of the first reference point O₁ in the first direction X and the second reference point O₂ in the first direction X are designed such that the difference therebetween in the first direction X is the first constant (when the first constant is zero, these two coordinate values in the first direction X are the same as each other) and the coordinate values of the third reference point O₃ in the second direction Y and the second reference point O₂ in the second direction Y are designed such that the difference therebetween in the second direction Y is the second constant (when the second constant is zero, these two coordinate values in the second direction Y are the same as each other),then, centerline of each of the first solid sub-patterns 101 extending in the second direction Y can be obtained by extracting side edges thereof, and centerline of each of the second solid sub-patterns 302 extending in the first direction X can be obtained by extracting side edges thereof.

In a specific embodiment, for example as shown in FIG. 18(a) and FIG. 18(b), a distance between respective centerline of each of the first solid sub-patterns 101 parallel to the second direction Y and the second reference point O₂ is defined as: an absolute value of a difference between the coordinate value, in the first direction X, of respective centerline of each of the first solid sub-patterns 101 parallel to the second direction Y and the coordinate value of the second reference point O₂ in the first direction X; and a distance between respective centerline of each of the second solid sub-patterns 302 parallel to the first direction X and the second reference point O₂ is defined as: an absolute value of a difference between the coordinate value, in the second direction Y, of respective centerline of each second solid sub-pattern 302 parallel to the first direction X and the coordinate value of the second reference point O₂ in the second direction Y.

In a more specific embodiment, for example as shown in FIG. 18(a) and FIG. 18(b), the coordinate value, in the direction X, of respective centerline of each of the first solid sub-patterns 101 parallel to the second direction Y is defined as a mean value of the coordinate values, in the first direction X, of respective two opposite side edges of each of the first solid sub-patterns 101 extending in the second direction Y, i.e., e′=(a′+b′)/2 and f′=(c′+d′)/2, as illustrated; and the coordinate value, in the second direction Y, of respective centerline of each of the second solid sub-patterns 302 parallel to first direction X is defined as a mean value of the coordinate values, in the second direction Y, of respective two opposite side edges of each of the second solid sub-patterns 302 extending in the first direction X, i.e., k′=(g′+h′)/2 and l′=(i′+j′)/2, as illustrated. In the specific implementation, by way of example, this is realized by performing edge extraction along the second direction Y for the respective first solid sub-images imaged from each of the first solid sub-patterns 101 in a single-pass SEM image so as to obtain centerlines of the two first solid sub-images extending in the second direction Y, and by performing edge extraction along the first direction X for the respective second solid sub-images imaged from each of the second solid sub-patterns 302 in a single-pass SEM image so as to obtain centerlines of the two second solid sub-images extending in the first direction X.

Moreover, based on the embodiments of the overlay alignment mark among the three layers and the definition of deviations among the three layers in the first direction X and in the second direction Y, respectively, as described above, in order to calculate the coordinate values of the second reference point O₂ in the first direction X and in the second direction Y, (i.e., to obtain the specific position of the second reference point O₂), then, in some embodiments, by way of example, as illustrated in FIG. 17(a) and FIG. 17(b), it is also required to design the overlay alignment mark such that, each type of the two first hollowed sub-patterns 201 and the two second hollowed sub-patterns 202 may be designed such that two hollowed sub-patterns in said type not only have central symmetry to each other about the second reference point O₂ but also have mirror symmetry to each other with respect to the second reference point O₂. Thereby, coordinate value of the second reference point O₂ in the first direction X may be obtained based on the two first hollowed sub-patterns 201, and coordinate value of the second reference point O₂ in the second direction Y may be obtained based on the two second hollowed sub-patterns 202.

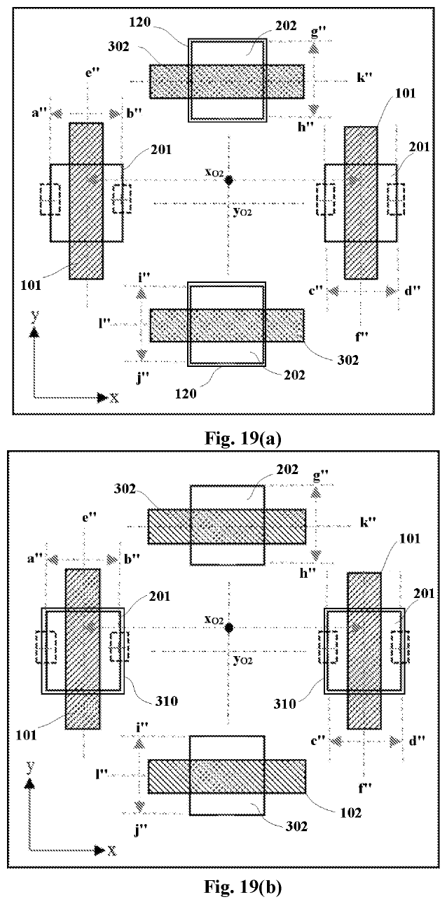

FIG. 19(a) shows in more detail a first way by which the coordinate values of the symmetrical center of the portion of the overlay alignment mark (as illustrated in FIG. 14(a)) located in the second layer 2 can be obtained, based on the overlay alignment mark as arranged in FIG. 17(a); and FIG. 19(b) shows in more detail a first way by which the coordinate values of the symmetrical center of the portion of the overlay alignment mark (as illustrated in FIG. 14(b)) located in the second layer 2 can be obtained, based on the overlay alignment mark as arranged in FIG. 17(b). In some specific embodiments, by way of example, as shown in FIG. 19(a) and FIG. 19(b), centerline of each of the first hollowed sub-patterns 201 extending in the second direction Y can be obtained by extracting side edges thereof, and centerline of each of the second hollowed sub-patterns 202 extending in the first direction X can be obtained by extracting side edges thereof. By way of example, respective two opposite side edges of each of the first hollowed sub-patterns 201 which are opposite to each other in the first direction X all extend in the second direction Y, and the coordinate value of the second reference point O₂ in the first direction X is defined as: a mean value of coordinate values, in the first direction X, of respective centerlines of the two first hollowed sub-patterns 201 parallel to the second direction Y; and respective two opposite side edges of each of the second hollowed sub-patterns 202 which are opposite to each other in the second direction Y all extend in the first direction X, and the coordinate value of the second reference point O₂ in the second direction Y is defined as: a mean value of coordinate values, in the second direction Y, of respective centerlines of the two second hollowed sub-patterns 202 parallel to the first direction X.

More specifically, by way of example, as shown in FIG. 19(a) and FIG. 19(b), the coordinate value, in the direction X, of respective centerline of each of the first hollowed sub-patterns 201 parallel to the second direction Y is further defined as a mean value of the coordinate values, in the first direction X, of respective two opposite side edges of each of the first hollowed sub-patterns 201 extending in the second direction Y, i.e., e″=(a″+b″)/2 and f′=(c″+d″)/2, as illustrated; and the coordinate value, in the second direction Y, of respective centerline of each of the second hollowed sub-patterns 202 parallel to first direction X is defined as a mean value of the coordinate values, in the second direction Y, of respective two opposite side edges of each of the second hollowed sub-patterns 202 extending in the first direction X, i.e., k″=(g″+h″)/2 and l″=(i″+j″)/2, as illustrated. In specific implementations, for example, this is specifically realized, by performing edge extraction along the second direction Y for the respective first hollowed sub-images imaged from each of the first hollowed sub-patterns 201 in a single-pass SEM image so as to obtain centerlines of the two first hollowed sub-images extending in the second direction Y, and then calculating a mean value of these two centerlines of the two first hollowed sub-images along the second direction Y, i.e., x₀₂=(e″+f″)/2; and by performing edge extraction along the first direction X for the respective second hollowed sub-images imaged from each of the second hollowed patterns 202 in a single-pass SEM image so as to obtain centerlines of the two second hollowed sub-images extending in the first direction X, and then calculating a mean value of these two centerlines of the two second hollowed sub-images along the first direction X, i.e., y₀₂=(k″+l″)/2.

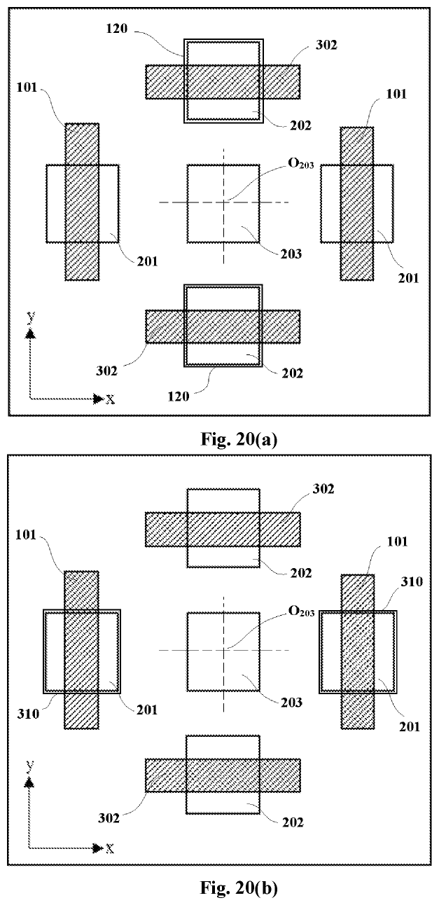

FIG. 20(a) shows in more detail a second way by which the coordinate values of the symmetrical center of the portion of the overlay alignment mark (as illustrated in FIG. 14(a)) located in the second layer 2 can be obtained, based on the overlay alignment mark as arranged in FIG. 17(a); and FIG. 20(b) shows in more detail a second way by which the coordinate values of the symmetrical center of the portion of the overlay alignment mark (as illustrated in FIG. 14(b)) located in the second layer 2 can be obtained, based on the overlay alignment mark as arranged in FIG. 17(b). In some other alternative specific embodiments, for example as shown in FIG. 20(a) and FIG. 20(b), by additionally adding a central hollowed sub-pattern 203 to the second pattern 20, and a geometric center of the central sub-pattern 203 serves as not only a symmetrical center of the two first hollowed sub-patterns 201 but also a symmetrical center of the two second hollowed sub-patterns 202, i.e., the geometric center of the central sub-pattern 203 serves as the second reference point O₂. Thereby, the coordinates of the symmetrical center of the central hollowed sub-pattern 203 as additionally added are the coordinates of the second reference point O₂. As an example, the second pattern 20 also comprises: a central hollowed sub-pattern 203, the central hollowed sub-pattern 203 is arranged centrally between the two first hollowed sub-patterns 201 and arranged centrally between the two second hollowed sub-patterns 202, with a geometric center of the central hollowed sub-pattern 203 functioning as the second reference point O₂.

More specifically, for example, as shown in FIG. 20(a) and FIG. 20(b), the center hollowed sub-pattern 203 is designed as a through-hole having a rectangular section. With this setting, for example, it is only required to measure the geometric center of the central hollowed sub-pattern 203 so as to obtain the coordinates of the second reference point O₂. For example, it is realized by graphical fitting of the central hollowed sub-pattern 203, and then calculating the geometric center of the fitted pattern. Thus, the coordinates of the second reference point O₂ are obtained in a simple way, avoiding the above indirect calculation. In a specific implementation, this is for example specifically realized in the following way: in a single-pass SEM image, a respective central hollowed sub-image imaged from the central hollowed sub-pattern 203 is fitted by graphical fitting, and then a geometric center of the fitted pattern is obtained.

In a condition that the overlay alignment mark is formed in three layers of the wafer, as in exemplary embodiments as above, e.g., it facilitates obtaining the deviation between the first layer 1 and the second layer 2 in the first direction X, by measuring the deviation between the first pattern 10 and the second pattern 20 in the first direction X and then subtracting the first constant from the deviation between the first pattern 10 and the second pattern 20 in the first direction X; and it also facilitates obtaining the deviation between the third layer 3 and the second layer 2 in the second direction Y, by measuring the deviation between the third pattern 30 and the second pattern 20 in the second direction Y and then subtracting the second constant from the deviation between the third pattern 30 and the second pattern 20 in the second direction Y. In alternative or additional embodiments, for example, under the same assumptions, by alternatively rotating the overlay alignment mark by 90 degrees, or by additionally setting another overlay alignment mark having the same patterns as the current overlay alignment mark but having its own orientation orthogonal to that of the current overlay alignment mark (for example, by providing the other overlay alignment mark having its patterns being the same as that of the current overlay alignment mark but its orientation being rotated 90 degrees as compared with that of the current overlay alignment mark, thus the first pattern 10, the second pattern 20 and the third pattern 30 of the other overlay alignment mark are specifically arranged such that, these patterns' respective arrangements in the first direction X and the second direction Y respectively are just opposite to those of pattern's in the overlay alignment mark as mentioned in the previous embodiments), then it also facilities obtaining the overlay error among the current layer, and previous layer and the second previous layer, based on the second definition of the deviation in at least one direction in the overlay error as described above, for example, it facilitates obtaining the deviation between the first layer 1 and the second layer 2 in the second direction Y, by measuring the deviation between the first pattern 10 and the second pattern 20 in the second direction Y and then subtracting a constant, which is a difference between coordinate values of respective reference points of the first pattern 10 and the second pattern 20 in the second direction, from the deviation between the first pattern 10 and the second pattern 20 in the second direction Y; and it also facilitates obtaining the deviation between the third layer 3 and the second layer 2 in the first direction X, by measuring the deviation between the third pattern 30 and the second pattern 20 in the first direction X and then subtracting a constant, which is a difference between coordinate values of respective reference points of the third pattern 30 and the second pattern 20 in the first direction X, from the deviation between the third pattern 30 and the second pattern 20 in the first direction X, without repeating details of such embodiments herein any more.

According to the general technical concept of embodiments of the disclosure, on the other hand, in the other aspect of embodiments of the disclosure, a method for measuring overlay error is also provided, comprising: providing the overlay alignment mark as above; and measuring an overlay error between different layers of the wafer by measuring a deviation between portions of the overlay alignment mark which are located in the different layers of the wafer.

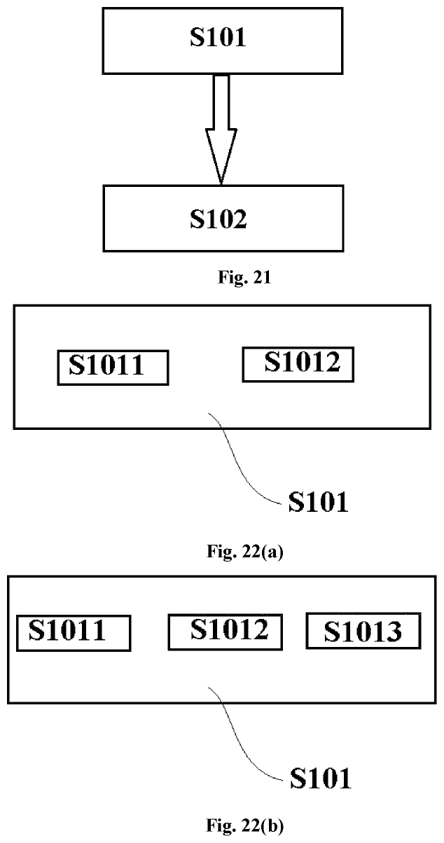

By way of example, a basic embodiment of the method for measuring overlay error is provided, e.g., as illustrated in FIG. 21, comprising:

S101: providing the overlay alignment mark in a wafer whose overlay error is to be measured; and

S102: measuring an overlay error between different layers of the wafer by measuring a deviation between portions of the overlay alignment mark which portions are located in the different layers of the wafer.

Specifically, as illustrated in FIG. 22(a), step S101, i.e., “providing the overlay alignment mark in the wafer whose overlay error is to be measured”, for example comprises:

S1011: providing a first pattern 10, comprising: providing two first solid sub-patterns 101 in a first layer 1 of the wafer, the two first solid sub-patterns 101 being provided opposite to each other in a first direction X and extending in a second direction Y perpendicular to the first direction X, respectively; and

S1012: providing a second pattern 20, comprising: providing two first hollowed sub-patterns 201 and two second hollowed sub-patterns 202 in a second layer 2 above the first layer 1 of the wafer, the two first hollowed sub-patterns 201 being provided opposite to each other in the first direction X, and two second hollowed sub-patterns 202 being provided opposite to each other in the second direction Y, two opposite side edges of each of the two first solid sub-patterns 101 which extend in the second direction Y being at least partially exposed from a respective one of the two first hollowed sub-patterns 201.

As mentioned above in view of FIG. 2(a) to FIG. 3(b), then, while performing a single-pass (i.e., single-shot) SEM imaging on the second pattern of the second layer 2, the first pattern 10 (specifically, the two first solid sub-patterns 101) in the first layer 1 which is at least partially exposed through the two first hollowed sub-patterns 201 of the second pattern can also be imaged. As such, in the single-pass SEM image as obtained, respective portions thereof which are imaged from the two first hollowed sub-patterns 201, the two second hollowed sub-patterns 202, and the two first solid sub-patterns 101 respectively are for example referred to as “first hollowed sub-images”, “second hollowed sub-images” and “first solid sub-images”, respectively.

As such, in contrast to a solution in the relevant art where respective portions of an overlay alignment mark located respectively in various layers of the wafer are arranged such that their respective orthographic projections on the wafer are staggered with respect to each other (i.e. they fail to overlap with each other at all) and thus it is necessary to acquire SEM patterns layer by layer, then, in the solution of embodiments of the present disclosure, the first solid sub-patterns 101 in the previous layer at least partially overlap with the first hollowed sub-patterns 201 in the current layer and thus are observable through the latter from above, then, respective portions of sub-images imaged from portions of the overlay alignment mark located in different layers (i.e. the first pattern 10 and the second pattern 20) can be obtained simultaneously merely by acquiring once a single-pass SEM image of both the previous layer and the current layer which overlap at least partially with each other, so as to avoid moving the SEM apparatus for many times during a layer-by-layer acquisition of SEM images by scanning thereby and an interference thus caused on measurement of the overlay error as applied by a displacement of the SEM apparatus relative to specific locations of the wafer to be scanned by electron beam emitted from the SEM apparatus, then it is not necessary to adjust energy of the electron beam of the SEM apparatus for many times; and the overlay error between the current layer and the previous layer (and more specifically, for example, a component of the overlay error for example in the first direction X), can be calculated based on the single-pass SEM image by acquiring the SEM image only once, simplifying steps of measuring the overlay error. Moreover, side edges of a respective first solid sub-image (e.g., outer side edge l₁ and inner side edge l₂, both of which extend in the second direction Y as illustrated in FIG. 1(a)) as imaged from side edges of each of the first solid sub-patterns 101 during the single-pass SEM image, are at least partially exposed from and are thus observable through a respective first hollowed sub-image as imaged from a respective first hollowed sub-pattern 201 which overlaps with said first solid sub-pattern 101.

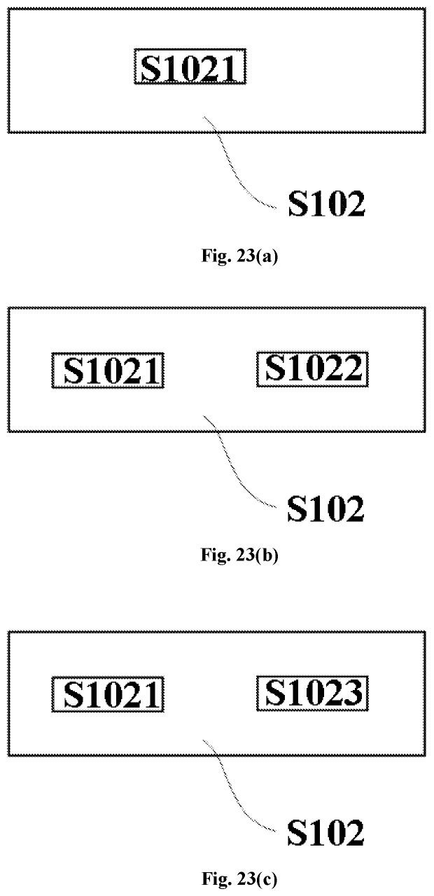

And more specifically, for example, in the step S1011, also in view of illustrations of FIG. 1(a), FIG. 2(a) and FIG. 3(b), “providing a first pattern 10, comprising: providing two first solid sub-patterns 101 in a first layer 1 of the wafer” further comprises: designing the two first solid sub-patterns 101 to be in the form of two solid patterns 101 having strip-shaped sections, both of which not only have central symmetry, to each other, about a first reference point O₁ located therebetween, but also have mirror symmetry to each other with respect to the first reference point O₁. And for example, in the step S1012, also in view of illustrations of FIG. 1(a), FIG. 2(b) and FIG. 3(a), “providing two first hollowed sub-patterns 201 and two second hollowed sub-patterns 202 in a second layer 2 above the first layer 1 of the wafer” further comprises: designing one type of the two first hollowed sub-patterns 201 and the two second hollowed sub-patterns 202 to be in the form of two through-holes having rectangular sections, which not only have central symmetry to each other about a second reference point O₂ located therebetween but also have mirror symmetry to each other with respect to the second reference point O₂. Moreover, as shown in FIG. 1(a) or preferably in FIG. 1(b), a coordinate value of the first reference point O₁ in the first direction X and a coordinate value of the second reference point O₂ in the first direction X are set such that a difference between these two coordinate values is a first constant, and these two coordinate values are equal to each other when the first constant is zero. In such a condition, specifically, for example as illustrated in FIG. 23(a), step S102, i.e., “measuring an overlay error between different layers of the wafer by measuring a deviation between portions of the overlay alignment mark which portions are located in the different layers of the wafer” for example at least comprises:

S1021: obtaining a deviation between the first layer 1 and the second layer 2 in the first direction X, by subtracting the first constant from a deviation between the first pattern 10 and the second pattern 20 in the first direction X as measured. Specifically, for example, the deviation between the first pattern 10 and the second pattern 20 in the first direction X can be measured, by measuring a difference between the coordinate value of the first reference point O₁ in the first direction X and the coordinate value of the second reference point O₂ in the first direction X.

In other words, by way of example, the deviation between the first pattern 10 and the second pattern 20 in the first direction X is for example directly defined as a difference between the coordinate value of the first reference point O₁ in the first direction X as practically measured and the coordinate value of the second reference point O₂ in the first direction X (the difference between the coordinate value of the first reference point O₁ in the first direction X and the coordinate value of the second reference point O₂ in the first direction X is supposed/expected in the design to be the first constant, for example zero). In addition to or as an alternative to the step S1021, the deviation between the first pattern 10 and the second pattern 20 in the second direction Y is for example directly defined as a difference between the coordinate value of the first reference point O₁ in the second direction Y as practically measured and the coordinate value of the second reference point O₂ in the second direction Y (the difference between the coordinate value of the first reference point O₁ in the second direction Y and the coordinate value of the second reference point O₂ in the second direction Y is supposed/expected in the design to be the second constant, for example zero).

As shown in FIG. 2(a) and FIG. 2(b), the first reference point O₁ and the second reference point O₂ are essentially respective projection points of two axes on the wafer both of which are respectively presented as the first axis and the second axis along the normal direction of the wafer in the sectional views of FIG. 2(a) and FIG. 2(b), and therefore these two reference points are each in the form of dot shape as illustrated in the top views of FIG. 1(a) and FIG. 1(b).

As shown in FIG. 4, more specifically, for example, “measuring a difference between the coordinate value of the first reference point O₁ in the first direction X and the coordinate value of the second reference point O₂ in the first direction X” comprises: obtaining the coordinate value of the first reference point O₁ in the first direction X, by measuring a half of a sum of mean values of coordinate values of respective two opposite side edges of the two first solid sub-patterns 101 extending in the second direction Y, in the first direction X. In the specific implementation, the edge extraction and coordinate calculation of each of the first solid sub-patterns 101 can be implemented by the following way: in the single-pass SEM image, based on edge extraction performed for the respective first solid sub-images imaged from each of the first solid sub-patterns 101 through a respective first hollowed sub-pattern 201 overlapping therewith, centerlines of the two first solid sub-image extending in the second direction Y can be obtained, and then a mean value of coordinate values, in the first direction X, of the centerlines of the two first solid sub-images extending in the second direction Y is calculated. The specific measurement and calculation are discussed in the embodiments as above with reference to FIG. 4, and will not be repeated here.

Moreover, more specifically, for example as shown in FIG. 4, in a condition that the two second hollowed sub-patterns 202 as illustrated are designed such that they not only have central symmetry, to each other, about the second reference point O₂, but also have mirror symmetry to each other with respect to the second reference point O₂, the coordinate value of the second reference point O₂ in the first direction X can be obtained. By way of example, “measuring a difference between the coordinate value of the first reference point O₁ in the first direction X and the coordinate value of the second reference point O₂ in the first direction X” comprises: obtaining the coordinate value of the second reference point O₂ in the first direction X, by performing graphical fitting for the two second hollowed sub-patterns 202 into circle patterns or ellipse patterns respectively, and calculating a mean value of the coordinate values, in the first direction X, of the geometric centers of the circle patterns or ellipse patterns (for example, by performing graphical fitting for the respective second hollowed sub-images as imaged from each of the second hollowed sub-patterns 202 in the single-pass SEM image to be a pattern (for example, a circle pattern or an ellipse pattern), and extracting the coordinate values, in the first direction X, of the geometric centers of respective patterns as obtained by the graphical fitting of the two second hollowed sub-images and in turn calculating the mean value of these coordinate values of the geometric centers). In the specific implementation, the graphical fitting and calculation of coordinates of respective geometric center of each of the second hollowed sub-patterns 202 can be realized by performing graphical fitting and extracting the geometric center based on the respective second hollowed sub-image imaged from each of the second hollowed sub-patterns 202 in the single-pass SEM image, and the specific measurement and calculation are discussed in the embodiments as above with reference to FIG. 4 and FIG. 5, and will not be repeated here.

In alternative or additional embodiments, by alternatively rotating the overlay alignment mark by 90 degrees, or by additionally setting another overlay alignment mark having the same patterns as the current overlay alignment mark but having its own orientation orthogonal to that of the current overlay alignment mark (for example, by providing the other overlay alignment mark having its patterns being the same as that of the current overlay alignment mark but its orientation being rotated 90 degrees as compared with that of the current overlay alignment mark, thus the first pattern 10 and the second pattern 20 of the other overlay alignment mark are specifically arranged such that, these patterns' respective arrangements in the first direction X and the second direction Y respectively are just opposite to those of pattern's in the overlay alignment mark as mentioned in the previous embodiments), then it also facilities that, based on the first definition as described above, the component of the overlay error between the current layer and the previous layer, for example in the second direction Y, is obtained in relatively simplified step(s), without repeating details of such embodiments herein any more.

As shown in FIG. 5 and in view of above embodiments, in a further extended embodiment, provided that for the existing pattern on the wafer, in a condition that two pairs of hollowed features are formed in the second layer 2, with two imaginary lines connecting between geometric centers of respective pairs in the two pairs of hollowed features extending in two mutually orthogonal directions, respectively; and a pair of solid features which are at least partially exposed from a respective pair of the hollowed features are formed in the first layer 1, with the pair of solid features having respective strip-shaped sections extending in one of the two mutually orthogonal directions, respectively, then, the pair of solid features then function as the two first solid sub-patterns 101, and the respective pair of the hollowed features from which the pair of solid features are at least partially exposed then function as the two first hollowed sub-patterns 201, while the other pair of the hollowed features function as the second hollowed sub-patterns 202. As such, based on aforementioned definition of the deviation in the overlay error, in at least one direction, then a portion of graphic features of the existing patterns on both the previous layer and the current layer can be used as the overlay alignment mark, without additionally forming a specialized/dedicated overlay alignment mark. Thus, the component of the overlay error between the current layer and the previous layer, for example in the first direction X, is obtained in relatively simplified step(s). The specific measurement and calculation are discussed in the embodiments as above with reference to FIG. 5, and will not be repeated here.

In alternative or additional embodiments, for example, under the same assumptions, by alternatively rotating the overlay alignment mark by 90 degrees, or by additionally setting another overlay alignment mark having the same patterns as the current overlay alignment mark but having its own orientation orthogonal to that of the current overlay alignment mark (for example, by providing the other overlay alignment mark having its patterns being the same as that of the current overlay alignment mark but its orientation being rotated 90 degrees as compared with that of the current overlay alignment mark, thus the first pattern 10 and the second pattern 20 of the other overlay alignment mark are specifically arranged such that, these patterns' respective arrangements in the first direction X and the second direction Y respectively are just opposite to those of pattern's in the overlay alignment mark as mentioned in the previous embodiments (for example, in the other overlay alignment mark, the direction Y essentially functions as its first direction and the direction X functions as its second direction)), then it facilities that, a portion of graphic features of the existing pattern on both the previous layer and the current layer can be used as the overlay alignment mark, based on the first definition of the deviation in at least one direction in the overlay error as described above, without additionally forming a specialized/dedicated overlay alignment mark. Thus, the component of the overlay error between the current layer and the previous layer, for example in the second direction Y, is obtained in relatively simplified step(s), without repeating details of such embodiments herein any more.

Furthermore, based on the basic embodiment of the aforementioned method for measuring overlay error, as shown in FIG. 22(a) in view of FIG. 6, for a condition where the overlay alignment mark is formed in two layers of the wafer, by way of example, specifically, in the step S1011, “providing a first pattern 10” further comprises: providing two second solid sub-patterns 102 in the first layer 1 of the wafer, the two second solid sub-patterns 102 being provided opposite to each other in the second direction Y and extending in the first direction X respectively, and two opposite side edges of each of the two second solid sub-patterns 102 which extend in the first direction X being at least partially exposed from a respective one of the two second hollowed sub-patterns 202.

As discussed in above embodiments in view of FIG. 2(a) to FIG. 3(b), and based on FIG. 7(a) to FIG. 8(b), then, while performing a single-pass (i.e., single-shot) SEM imaging on the second pattern of the second layer 2, the first pattern 10 (specifically, the two first solid sub-patterns 101 and the two second solid sub-patterns 102) in the first layer 1 which is at least partially exposed through the two first hollowed sub-patterns 201 and the two second hollowed sub-patterns 202 of the second pattern can also be imaged. As such, in the single-pass SEM image as obtained, respective portions thereof which are imaged from the two first hollowed sub-patterns 201, the two second hollowed sub-patterns 202, the two first solid sub-patterns 101 and the two second solid sub-patterns 102 respectively are for example referred to as “first hollowed sub-images”, “second hollowed sub-images”, “first solid sub-images”, and “second solid sub-images”, respectively. Moreover, then, in the single-pass SEM image, side edges of a respective second solid sub-image (e.g., outer side edge l₃ and inner side edge l₄, both of which extend in the first direction X as illustrated in FIG. 6) as imaged from side edges of each of the second solid sub-pattern 102, are at least partially exposed from and are thus observable through a respective second hollowed sub-image as imaged from a respective second hollowed sub-pattern 202 which overlaps with said second solid sub-pattern 102.

And, more specifically, for example in the Step S1011, also in view of FIG. 6, FIG. 7(b) and FIG. 8(b), “providing two second solid sub-patterns 102 in the first layer 1 of the wafer” further comprises: designing the two second solid sub-patterns 102 to be in the form of two solid patterns having strip-shaped sections, both of which not only have central symmetry, to each other, about the first reference point O₁, but also have mirror symmetry to each other with respect to the first reference point O₁, with a coordinate value of the first reference point O₁ in the second direction Y and a coordinate value of the second reference point O₂ in the second direction Y being set such that a difference between these two coordinate values is a second constant, and these two coordinate values are equal to each other when the second constant is zero. In such a condition, specifically, for example as illustrated in FIG. 23(b) in view of FIG. 6, step S102, i.e., “measuring an overlay error between different layers of the wafer by measuring a deviation between portions of the overlay alignment mark which portions are located in the different layers of the wafer” for example at least comprises:

S1021: obtaining a deviation between the first layer 1 and the second layer 2 in the first direction X, by subtracting the first constant from a deviation between the first pattern 10 and the second pattern 20 as measured in the first direction X; and

S1022: obtaining a deviation between the first layer 1 and the second layer 2 in the second direction Y, by subtracting the second constant from a deviation between the first pattern 10 and the second pattern 20 as measured in the second direction Y.

As discussed above, based on a combination of the specific layered arrangement based on the overlay alignment mark shown in the sectional view of FIG. 7(a) and FIG. 7(b) with the plane layout of the parts located in each of layers of the overlay alignment mark shown in the top view of FIG. 8(a) and FIG. 8(b), then, with such a specific setting, in a condition that the overlay alignment mark is formed in two layers (i.e., the current layer and the previous layer) of the wafer, and a difference between coordinate values of centers of respective portions of the overlay alignment mark in the two layers (for example, the first reference point O₁ and the second reference point O₂, as above) in the first direction X is the first constant and a difference between coordinate values of centers of respective portions of the overlay alignment mark in the two layers (for example, the first reference point O₁ and the second reference point O₂, as above) in the second direction Y is also the second constant, that is, the first reference point O₁ and the second reference point O₂ are slightly offset from each other in advance (for example, the difference between the two coordinate values in the first direction is a constant, and/or the difference between the two coordinate values in the second direction is a constant; furthermore, when the two constants in the first direction and in the second direction are both zero, respectively, the first reference point O₁ and the second reference point O₂ coincide with each other), then as shown in FIG. 9, according to the second definition of the overlay error between the two layers, as above, more specifically, in the Step S1021, measuring a deviation between the first pattern 10 and the second pattern 20 in the first direction X for example comprises: measuring ½ of a difference between distances between respective centerlines of the two first solid sub-patterns 101 parallel to the second direction Y and the second reference point O₂; and in the Step S1022, measuring a deviation between the first pattern 10 and the second pattern 20 in the second direction Y for example comprises: measuring ½ of a difference between distances between respective centerlines of the two second solid sub-patterns 102 parallel to the first direction X and the second reference point O₂.

Furthermore, in order to specifically implementing the calculation of the overlay error, on the one hand, it is required to obtain coordinate values, in the first direction X, of respective centerlines of the two first solid sub-patterns 101 parallel to the second direction Y, and to measure coordinate values, in the second direction Y, of respective centerlines of the two second solid sub-patterns 102 parallel to the first direction X; on the other hand, it is required to obtain respective coordinate values, in the first direction X and in the second direction Y, of the second reference point O₂, respectively, i.e., to obtain the specific position of the second reference point O₂. In the specific implementation, in order to obtain not only the coordinate values, in the first direction X, of respective centerlines of the two first solid sub-patterns 101 parallel to the second direction Y, but also the coordinate values, in the second direction Y, of respective centerlines of the two second solid sub-patterns 102 parallel to the first direction X, then, by way of example, this is specifically realized by performing edge extraction along the second direction Y for the respective first solid sub-images imaged from each of the first solid sub-patterns 101 in a single-pass SEM image so as to obtain centerlines of the two first solid sub-images extending in the second direction Y, and by performing edge extraction along the first direction X for the respective second solid sub-images imaged from each of the second solid patterns 102 in a single-pass SEM image so as to obtain centerlines of the two second solid sub-images extending in the first direction X. The specific measurement and calculation are discussed in the embodiments as above with reference to FIG. 10 in a way similar to that as above, and will not be repeated here. Moreover, by way of example, in view of the aforementioned embodiments based on

FIGS. 11, 12 and 13, i.e., based on a first way (specifically, respective centerlines of the first hollowed sub-patterns 201 and the second hollowed sub-patterns 202 are obtained by performing edge extraction for the first hollowed sub-patterns 201 and the second hollowed sub-patterns 202, and the coordinate value of the second reference point O₂ can in turn be calculated with a mean value of these centerlines), a second way (the coordinate value of the second reference point O₂ can be obtained by performing graphical fitting on the first hollowed sub-patterns 201 and the second hollowed sub-patterns 202), and a third way (the coordinate value of the second reference point O₂ can be obtained by adding a central hollowed sub-pattern 203 and then acquiring the coordinates of a center of the central hollowed sub-pattern to serve as the second reference point O₂) for obtaining the coordinate value of symmetrical center of the portion of overlay alignment mark as illustrated in FIG. 6 located in the first layer, based on the overlay alignment mark as arranged in FIG. 9, then, the specific coordinate values of the second reference point O₂ (in both the first direction X and the second direction Y) can be obtained by measurement.

The first way as above in view of FIG. 11, in the specific implementation, for example, is realized by: performing edge extraction along the second direction Y for the respective first hollowed sub-images imaged from each of the first hollowed sub-patterns 201 in a single-pass SEM image and performing edge extraction along the first direction X for the respective second hollowed sub-images imaged from each of the second hollowed patterns 202 in a single-pass SEM image. The specific measurement and calculation are discussed in the embodiments as above with reference to FIG. 11 as above, and will not be repeated here.

The second way as above in view of FIG. 12, in the specific implementation, for example, is realized by: performing graphical fitting and center extraction for respective first hollowed sub-image imaged from each of the first hollowed sub-patterns 201 and for respective second hollowed sub-image imaged from each of the second hollowed sub-patterns 202, respectively, in the single-pass SEM image. The specific measurement and calculation are discussed in the embodiments as above with reference to FIG. 12 as above, and will not be repeated here.

The third way as above in view of FIG. 13, in the specific implementation, for example, is realized by: performing graphical fitting and center extraction for a respective central hollowed sub-image imaged from the central hollowed sub-pattern 203 in a single-pass SEM image which is additionally provided (which is arranged centrally between the two first hollowed sub-patterns 201 and arranged centrally between the two second sub-patterns 202, with a geometric center of the central hollowed sub-pattern 203 functioning as the second reference point O₂). The specific measurement and calculation are discussed in the embodiments as above with reference to FIG. 13 as above, and will not be repeated here.

As an alternative to the embodiments shown in FIG. 6 to FIG. 13, furthermore, based on the basic embodiment of the above-mentioned method for measuring overlay error, as shown in FIG. 22(b) in view of FIG. 14(a) and FIG. 14(b), for a condition where the overlay alignment mark is formed in three layers of the wafer, for example, specifically, step S101, i.e., “providing the overlay alignment mark in a wafer whose overlay error is to be measured”, for example further comprises:

S1013: providing a third pattern 30. And the step of “providing a third pattern 30” comprises: providing two second solid sub-patterns 302 in a third layer 3 of the wafer which layer is located below the first layer 1 of the wafer or located between the first layer 1 and the second layer 2, the two second solid sub-patterns 302 being provided opposite to each other in the second direction Y and extending in the first direction X respectively, and two opposite side edges of each of the two second solid sub-patterns 302 extending in the first direction X being at least partially exposed from a respective one of the two second hollowed sub-patterns 202.

The third pattern 30 is formed in the third layer 3 of the wafer. For example, the third layer 3 is located below the first layer 1 of the wafer (for example, as shown in FIG. 15(a) and FIG. 15(b), where the first layer 1 serves as a previous layer and the third layer 3 serves as a second previous layer), or the third layer 3 is located between the first layer 1 and the second layer 2 (for example, as shown in FIG. 15(c) and FIG. 15(d), where the third layer 3 serves as a previous layer, and the first layer 1 serves as a second previous layer).

More specifically, for example, based on a combination of the specific layered arrangement based on the overlay alignment mark shown in the sectional view of FIG. 15(a) and FIG. 15(b) with the plane layout of the parts located in each of layers of the overlay alignment mark shown in the top view of FIG. 16(a) to FIG. 16(c), then in a condition that the third layer 3 is located below the first layer 1, by way of example, specifically, then in the step S1011 as illustrated in FIG. 22(b), “providing a first pattern 10” further comprises: providing two third hollowed sub-patterns 120 in the first layer 1, the two third hollowed sub-patterns 120 being provided opposite to each other in the second direction Y and at least partially overlapping with the two second hollowed sub-patterns 202, and two opposite side edges of each of the two second solid sub-patterns 302 extending in the first direction X being at least partially exposed from a respective third hollowed sub-pattern 120 and a respective second hollowed sub-pattern 202.

Or, alternatively, for example, based on a combination of the specific layered arrangement based on the overlay alignment mark shown in the sectional view of FIG. 15(c) and FIG. 15(d) with the plane layout of the parts located in each of layers of the overlay alignment mark shown in the top view of FIG. 16(d) to FIG. 16(f), then in a condition that the third layer 3 is located between the first layer 1 and the second layer 2, by way of example, specifically, then in the step S1013 as illustrated in FIG. 22(b), “providing a third pattern 30” further comprises: providing two third hollowed sub-patterns 310 in the third layer 3,the two third hollowed sub-patterns 310 being provided opposite to each other in the first direction X and at least partially overlapping with the two first hollowed sub-patterns 201, two opposite side edges of each of the two first solid sub-patterns 101 extending in the second direction Y being at least partially exposed from a respective third hollowed sub-pattern 310 and in turn from a respective first hollowed sub-pattern 201, and two opposite side edges of each of the two second solid sub-patterns 302 extending in the first direction X being at least partially exposed from a respective second hollowed sub-pattern 202.

Similar to the previous discussion in view of FIG. 2(a) to FIG. 3(b) and FIG. 7(a) to FIG. 8(b), and based on a combination of the specific layered arrangement based on the overlay alignment mark shown in the sectional views of FIG. 15(a) and FIG. 15(b) with the plane layout of the parts located in each of layers of the overlay alignment mark shown in the top views of FIG. 16(a) to FIG. 16(c), Therefore, while performing a single-pass SEM imaging on the second pattern 20 in the second layer 2, the two first solid sub-patterns 101 of the first pattern 10 in the first layer 1 which are at least partially exposed through the first hollowed sub-patterns 201 of the second pattern 20 can also be imaged simultaneously, and the two second solid sub-patterns 302 of the third pattern 30 in the third layer 3 which are at least partially exposed through the third hollowed sub-patterns 120 of the first pattern 10 and the second hollowed sub-patterns 202 of the second pattern 20 can also be imaged simultaneously. As such, in the single-pass SEM image as obtained, respective portions of the SEM image which are imaged from the two first hollowed sub-patterns 201, the two second hollowed sub-patterns 202, the two third hollowed sub-patterns 120, and the two first solid sub-patterns 101, the two second solid sub-patterns 302 respectively are for example referred to as “first hollowed sub-images”, “second hollowed sub-images”, “third hollowed sub-images”, “first solid sub-images” and “second solid sub-images” respectively. Moreover, in the single-pass SEM image, side edges of a respective second solid sub-image (e.g., outer side edge l_{3′} and inner side edge l_{4′}, both of which extend in the first direction X as illustrated in FIG. 14(a)) as imaged from side edges of each of the second solid sub-patterns 302, are at least partially exposed from and are thus observable through a respective third hollowed sub-image as imaged from a respective third hollowed sub-pattern 120 and a respective second hollowed sub-image as imaged from a respective second hollowed sub-pattern 202, both of the respective third hollowed sub-pattern 120 and the respective second hollowed sub-pattern 202 overlapping with said second solid sub-pattern 302.

Alternatively, similar to the previous discussion in view of FIG. 2(a) to FIG. 3(b) and FIG. 7(a) to FIG. 8(b), by way of example, on the basis of a combination of the specific layered arrangement of the overlay alignment marks as shown in the sectional views of FIG. 15(c) and FIG. 15(d) with the plane layouts of the portions of the overlay alignment mark located in various layers as shown in the top views of FIG. 16(d) to FIG. 16(f), then, while performing a single-pass SEM imaging on the second pattern 20 in the second layer 2, the two second solid sub-patterns 302 of the third pattern 30 in the third layer 3 which are at least partially exposed through the second hollowed sub-patterns 202 of the second pattern 20 can also be imaged simultaneously, and the two first solid sub-patterns 101 of the first pattern 10 in the first layer 1 which are at least partially exposed through the third hollowed sub-patterns 310 of the third pattern and the first hollowed sub-patterns 201 of the second pattern 20 can also be imaged simultaneously. As such, in the single-pass SEM image as obtained, respective portions of the SEM image which are imaged from the two first hollowed sub-patterns 201, the two second hollowed sub-patterns 202, the two third hollowed sub-patterns 310, and the two first solid sub-patterns 101, the two second solid sub-patterns 302 respectively are for example referred to as “first hollowed sub-images”, “second hollowed sub-images”, “third hollowed sub-images”, “first solid sub-images” and “second solid sub-images” respectively. Then, in the single-pass SEM image, side edges of a respective second solid sub-image (e.g., outer side edge l_{3″} and inner side edge l_{4″}, both of which extend in the first direction X as illustrated in FIG. 14(b)) as imaged from side edges of each of the second solid sub-patterns 302, are at least partially exposed from and are thus observable through a respective second hollowed sub-image as imaged from a respective second hollowed sub-pattern 202 overlapping with said second solid sub-pattern 302.

And more specifically, for example, in step s1013, also in view of FIG. 14(a) and FIG. 14(b), FIG. 15(b) and FIG. 15(d), as well as FIG. 16(c) and FIG. 16(e), “providing two second solid sub-patterns 302 in a third layer 3 of the wafer which layer is located below the first layer 1 of the wafer or located between the first layer 1 and the second layer 2” further comprises: designing the two second solid sub-patterns 302 to be in the form of two solid patterns having strip-shaped sections, both of which not only have central symmetry, to each other, about the third reference point O₃, but also have mirror symmetry to each other with respect to the third reference point O₃, with a coordinate value of the third reference point O₃ in the second direction Y and a coordinate value of the second reference point O₂ in the second direction Y being set such that a difference between these two coordinate values is a second constant, and these two coordinate values are equal to each other when the second constant is zero. In such a condition, specifically, for example as illustrated in FIG. 23(c), step S102, i.e., “measuring an overlay error between different layers of the wafer by measuring a deviation between portions of the overlay alignment mark which portions are located in the different layers of the wafer” for example at least comprises:

S1021: obtaining a deviation between the first layer 1 and the second layer 2 in the first direction X, by subtracting the first constant from a deviation between the first pattern 10 and the second pattern 20 as measured in the first direction X; and

S1023: obtaining a deviation between the third layer 3 and the second layer 2 in the second direction Y, by subtracting the second constant from a deviation between the third pattern 30 and the second pattern 20 as measured in the second direction Y.

As shown in FIG. 15(a) to FIG. 15(d), the first reference point O₁, the second reference point O₂ and the third reference point O₃ are essentially respective projection points of three axes on the wafer all of which are respectively presented as the first axis, the second axis and the third axis along the normal direction of the wafer in the sectional views of FIG. 15(a) to FIG. 15(d), and therefore these three reference points are each in the form of dot shape as illustrated in the top views of FIG. 14(a) and FIG. 14(b).

As discussed above, based on a combination of the specific layered arrangement based on the overlay alignment mark shown in the sectional view of FIG. 15(a) to FIG. 15(d) with the plane layout of the parts located in each of layers of the overlay alignment mark shown in the top view of FIG. 16(a) to FIG. 16(f), then, with such a specific setting, in a condition that the overlay alignment mark is formed in three layers (i.e., the current layer, the previous layer and the second previous layer) of the wafer, and as illustrated in FIG. 15(a) an FIG. 15(b), a difference between a coordinate value of a center of the second pattern 20 in the second layer 2 (e.g., the aforementioned second reference point O₂) and a coordinate value of a center of the first pattern 10 in the first layer 1 (e.g., the aforementioned first reference point O₁) of the overlay alignment mark in the first direction X is the first constant, and a difference between a coordinate value of the center of the second pattern 20 in the second layer 2 (e.g., the aforementioned second reference point O₂) and a coordinate value of a center of the third pattern 30 in the third layer 3 (e.g., the aforementioned third reference point O₃) of the overlay alignment mark in the second direction Y is the second constant, then as shown in FIG. 9, according to the second definition of the overlay error between the two layers, as above, more specifically according to the second definition of the overlay error between the two layers as shown in FIG. 9, more specifically:

In the Step S1021, measuring a deviation between the first pattern 10 and the second pattern 20 in the first direction X for example comprises: measuring ½ of a difference between distances between respective centerlines of the two first solid sub-patterns 101 parallel to the second direction Y and the second reference point O₂, the respective centerlines of the two first solid sub-patterns 101 being defined by respective two opposite side edges of each of the first solid sub-patterns 101 extending in the second direction Y; and in the Step S1023, measuring a deviation between the third pattern 30 and the second pattern 20 in the second direction Y for example comprises: measuring ½ of a difference between distances between respective centerlines of the two second solid sub-patterns 302 parallel to the first direction X and the second reference point O₂, the respective centerlines of the two second solid sub-patterns 302 being defined by respective two opposite side edges of each of the second solid sub-patterns 302 extending in the first direction X.

Furthermore, in order to specifically implementing the calculation of the overlay error, on the one hand, it is required to obtain coordinate values, in the first direction X, of respective centerlines of the two first solid sub-patterns 101 parallel to the second direction Y, and to measure coordinate values, in the second direction Y, of respective centerlines of the two second solid sub-patterns 302 parallel to the first direction X; on the other hand, it is required to obtain respective coordinate values, in the first direction X and in the second direction Y, of the second reference point O₂, respectively, i.e., to obtain the specific position of the second reference point O₂. In the specific implementation, in order to obtain not only the coordinate values, in the first direction X, of respective centerlines of the two first solid sub-patterns 101 parallel to the second direction Y, but also the coordinate values, in the second direction Y, of respective centerlines of the two second solid sub-patterns 302 parallel to the first direction X, then, by way of example, this is realized by performing edge extraction along the second direction Y for the respective first solid sub-images imaged from each of the first solid sub-patterns 101 in a single-pass SEM image so as to obtain centerlines of the two first solid sub-images extending in the second direction Y, and by performing edge extraction along the first direction X for the respective second solid sub-images imaged from each of the second solid sub-patterns 302 in a single-pass SEM image so as to obtain centerlines of the two second solid sub-images extending in the first direction X. The specific measurement and calculation are discussed in the embodiments as above with reference to FIG. 18(a) and FIG. 18(b) in a way similar to the embodiment of FIG. 10 as above, and will not be repeated here.

Moreover, by way of example, in view of the aforementioned embodiments based on FIGS. 11, 12 and 13, for example based on FIG. 19(a) and FIG. 19(b), and FIG. 20(a) and FIG. 20(b), i.e., based on one way (specifically, respective centerlines of the first hollowed sub-patterns 201 and the second hollowed sub-patterns 202 are obtained by performing edge extraction for the first hollowed sub-patterns 201 and the second hollowed sub-patterns 202, and the coordinate value of the second reference point O₂ can in turn be calculated with a mean value of these centerlines), and another alternative way (the coordinate value of the second reference point O₂ can be obtained by adding a central hollowed sub-pattern 203 and then acquiring the coordinates of a center of the central hollowed sub-pattern to serve as the second reference point O₂) for obtaining the coordinate value of symmetrical center of the portion of overlay alignment mark as illustrated in FIG. 14(a) and FIG. 14(b) located in the second layer 2, based on the overlay alignment mark as arranged in either one of FIG. 17(a) and FIG. 17(b), then, the specific coordinate values of the second reference point O₂ (in both the first direction X and the second direction Y) can be obtained by measurement.

In a condition that the overlay alignment mark is formed in three layers of the wafer, as in exemplary embodiments as above, e.g., it facilitates obtaining the deviation between the first layer 1 and the second layer 2 in the first direction X, by measuring the deviation between the first pattern 10 and the second pattern 20 in the first direction X and then subtracting the first constant from the deviation between the first pattern 10 and the second pattern 20 in the first direction X; and it also facilitates obtaining the deviation between the third layer 3 and the second layer 2 in the second direction Y, by measuring the deviation between the third pattern 30 and the second pattern 20 in the second direction Y and then subtracting the second constant from the deviation between the third pattern 30 and the second pattern 20 in the second direction Y. In alternative or additional embodiments, for example, under the same assumptions, by alternatively rotating the overlay alignment mark by 90 degrees, or by additionally setting another overlay alignment mark having the same patterns as the current overlay alignment mark but having its own orientation orthogonal to that of the current overlay alignment mark (for example, by providing the other overlay alignment mark having its patterns being the same as that of the current overlay alignment mark but its orientation being rotated 90 degrees as compared with that of the current overlay alignment mark, thus the first pattern 10, the second pattern 20 and the third pattern 30 of the other overlay alignment mark are specifically arranged such that, these patterns' respective arrangements in the first direction X and the second direction Y respectively are just opposite to those of pattern's in the overlay alignment mark as mentioned in the previous embodiments), then it also facilities obtaining the overlay error among the current layer, and previous layer and the second previous layer, based on the second definition of the deviation in at least one direction in the overlay error as described above, for example, it facilitates obtaining the deviation between the first layer 1 and the second layer 2 in the second direction Y, by measuring the deviation between the first pattern 10 and the second pattern 20 in the second direction Y and then subtracting a constant, which is a difference between coordinate values of respective reference points of the first pattern 10 and the second pattern 20 in the second direction, from the deviation between the first pattern 10 and the second pattern 20 in the second direction Y; and it also facilitates obtaining the deviation between the third layer 3 and the second layer 2 in the first direction X, by measuring the deviation between the third pattern 30 and the second pattern 20 in the first direction X and then subtracting a constant, which is a difference between coordinate values of respective reference points of the third pattern 30 and the second pattern 20 in the first direction, from the deviation between the third pattern 30 and the second pattern 20 in the first direction X, without repeating details of such embodiments herein any more.

The method for measuring overlay error correspondingly comprises all the graphic features and corresponding advantages of the overlay alignment mark as above, and will not be repeated here.

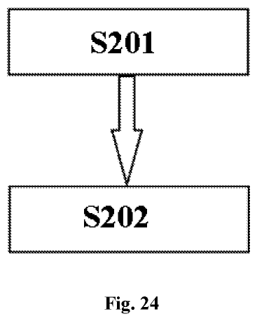

According to the general technical concept of embodiments of the disclosure, in another aspect of embodiments of the disclosure, for example as shown in FIG. 24, method for overlay alignment is also provided, comprising:

S201: performing the method for measuring overlay error as above; and

S202: compensating for the overlay error between different layers of the wafer, by offsetting the different layers of the wafer relative to each other.

In the step S202, for example, the relative offset value between the current layer and at least one previous layer (e.g., the previous layer, and/or the second previous layer) in the first direction X which is to be applied to the wafer can be calculated, by the deviation in the first direction X (i.e., ΔX). The relative offset value between or among various layers in the first direction X is opposite to the relative deviation (ΔX) between or among the various layers in the first direction X, or has any value suitable for adjusting the deviation in the first direction X (i.e., ΔX). And for example, the relative offset value between the current layer and at least one previous layer (e.g., the previous layer, and/or the second previous layer) in the second direction Y which is to be applied to the wafer can be calculated, by the deviation in the second direction Y (i.e., ΔY). The relative offset value between or among various layers in the second direction Y is opposite to the relative deviation (ΔY) between or among the various layers in the second direction Y, or has any value suitable for adjusting the deviation in the second direction Y (i.e., ΔY).

The method for overlay alignment correspondingly comprises all the graphic features and corresponding advantages of the overlay alignment mark as above and the method for measuring overlay error as above, and will not be repeated here.

Further embodiments are disclosed in the subsequent numbered clauses:
1. An overlay alignment mark formed on a wafer to be detected, comprising: a first pattern located in a first layer of the wafer, the first pattern comprising two first solid sub-patterns which are provided opposite to each other in a first direction and extend in a second direction perpendicular to the first direction, respectively; and
a second pattern located in a second layer, above the first layer, of the wafer, the second pattern comprising two first hollowed sub-patterns which are provided opposite to each other in the first direction and two second hollowed sub-patterns which are provided opposite to each other in the second direction,
wherein two opposite side edges of each of the two first solid sub-patterns extending in the second direction are at least partially exposed from a respective one of the two first hollowed sub-patterns.
2. The overlay alignment mark according to clause 1, wherein,
the two first solid sub-patterns are designed to be in the form of two solid patterns having strip-shaped sections, both of which not only have central symmetry, to each other, about a first reference point located therebetween, but also have mirror symmetry to each other with respect to the first reference point;
one type of the two first hollowed sub-patterns and the two second hollowed sub-patterns is designed to be in the form of two through-holes having rectangular sections, which not only have central symmetry to each other about a second reference point located therebetween but also have mirror symmetry to each other with respect to the second reference point; and
a coordinate value of the first reference point in the first direction and a coordinate value of the second reference point in the first direction are set such that a difference between these two coordinate values is a first constant.
3. The overlay alignment mark according to clause 2, wherein an overlay error between different layers of the wafer is an overlay error between the first layer and the second layer, at least comprising:
a deviation between the first layer and the second layer in the first direction, which is defined by subtracting the first constant from a deviation between the first pattern and the second pattern in the first direction.
4. The overlay alignment mark according to clause 3, wherein the deviation between the first pattern and the second pattern in the first direction is defined as a difference between the coordinate value of the first reference point in the first direction and the coordinate value of the second reference point in the first direction.
5. The overlay alignment mark according to clause 4, wherein the coordinate value of the first reference point in the first direction is defined as a half of a sum of mean values of coordinate values of respective two opposite side edges of the two first solid sub-patterns extending in the second direction, in the first direction.
6. The overlay alignment mark according to clause 4 or 5, wherein the two second hollowed sub-patterns are designed to not only have central symmetry to each other about the second reference point but also have mirror symmetry to each other with respect to the second reference point.
7. The overlay alignment mark according to clause 6, wherein the coordinate value of the second reference point in the first direction is defined as a mean value of coordinate values, in the first direction, of geometric centers of circle patterns or ellipse patterns obtained by fitting from the two second hollowed sub-patterns.
8. The overlay alignment mark according to clause 6 or 7, wherein two pairs of hollowed features are formed in the second layer, with two imaginary lines connecting between geometric centers of respective pairs in the two pairs of hollowed features extending in two mutually orthogonal directions, respectively; and a pair of solid features which are at least partially exposed from a respective pair of the hollowed features are formed in the first layer, with the pair of solid features having respective strip-shaped sections extending in one of the two mutually orthogonal directions, respectively, and
the pair of solid features then function as the two first solid sub-patterns, and the respective pair of the hollowed features from which the pair of solid features are at least partially exposed then function as the two first hollowed sub-patterns, while the other pair of the hollowed features function as the second hollowed sub-patterns.
9. The overlay alignment mark according to clause 2, wherein the first pattern further comprises two second solid sub-patterns which are provided opposite to each other in the second direction and extend in the first direction respectively; and
two opposite side edges of each of the two second solid sub-patterns extending in the first direction are at least partially exposed from a respective one of the two second hollowed sub-patterns.
10. The overlay alignment mark according to clause 9, wherein,
the two second solid sub-patterns are designed to be in the form of two solid patterns having strip-shaped sections, both of which not only have central symmetry, to each other, about the first reference point, but also have mirror symmetry to each other with respect to the first reference point; and
a coordinate value of the first reference point in the second direction and a coordinate value of the second reference point in the second direction are set such that a difference between these two coordinate values is a second constant.
11. The overlay alignment mark according to clause 10, wherein
an overlay error between different layers of the wafer is an overlay error between the first layer and the second layer, at least comprising:
a deviation between the first layer and the second layer in the first direction, which is defined by subtracting the first constant from a deviation between the first pattern and the second pattern in the first direction; and
a deviation between the first layer and the second layer in the second direction, which is defined by subtracting the second constant from a deviation between the first pattern and the second pattern in the second direction.
12. The overlay alignment mark according to clause 11, wherein, the deviation between the first pattern and the second pattern in the first direction is defined as ½ of a difference between distances between respective centerlines of the two first solid sub-patterns parallel to the second direction and the second reference point; and the deviation between the first pattern and the second pattern in the second direction is defined as ½ of a difference between distances between respective centerlines of the two second solid sub-patterns parallel to the first direction and the second reference point.
13. The overlay alignment mark according to clause 12, wherein,
a distance between respective centerline of each of the first solid sub-patterns parallel to the second direction and the second reference point, is defined as:
an absolute value of a difference between a mean value of the coordinate values of respective two opposite side edges of each of the first solid sub-patterns extending in the second direction, in the first direction and the coordinate value of the second reference point in the first direction; and
a distance between respective centerline of each of the second solid sub-patterns parallel to the first direction and the second reference point , is defined as:
an absolute value of a difference between a mean value of the coordinate values of respective two opposite side edges of each of the second solid sub-patterns extending in the first direction, in the second direction and the coordinate value of the second reference point in the second direction.
14. The overlay alignment mark according to clause 12 or 13, wherein each type of the two first hollowed sub-patterns and the two second hollowed sub-patterns is designed to not only have central symmetry to each other about the second reference point but also have mirror symmetry to each other with respect to the second reference point.
15. The overlay alignment mark according to clause 14, wherein,
the coordinate value of the second reference point in the first direction is defined as a half of a sum of mean values of coordinate values of respective two opposite side edges of the two first hollowed sub-patterns extending in the second direction, in the first direction; and
the coordinate value of the second reference point in the second direction is defined as a half of a sum of mean values of coordinate values of respective two opposite side edges of the two second hollowed sub-patterns extending in the first direction, in the second direction.
16. The overlay alignment mark according to clause 14, wherein,
the coordinate value of the second reference point in the first direction is defined as a mean value of coordinate values, in the first direction, of geometric centers of circle patterns or ellipse patterns obtained by fitting from the two first hollowed sub-patterns; and
the coordinate value of the second reference point in the second direction is defined as a mean value of coordinate values, in the second direction, of geometric centers of circle patterns or ellipse patterns obtained by fitting from the two second hollowed sub-patterns.
17. The overlay alignment mark according to clause 14, wherein,
the second pattern also comprises: a central hollowed sub-pattern, the central hollowed sub-pattern is arranged centrally between the two first hollowed sub-patterns and arranged centrally between the two second sub-patterns, with a geometric center of the central hollowed sub-pattern functions as the second reference point.
18. The overlay alignment mark according to clause 2, further comprising: a third pattern located in a third layer of the wafer which layer is located below the first layer of the wafer or located between the first layer and the second layer, the third pattern comprising two second solid sub-patterns which are provided opposite to each other in the second direction and extend in the first direction, respectively,
wherein two opposite side edges of each of the two second solid sub-patterns extending in the first direction are at least partially exposed from a respective one of the two second hollowed sub-patterns.
19. The overlay alignment mark according to clause 18, wherein,
the two second solid sub-patterns are designed to be in the form of two solid patterns having strip-shaped sections, both of which not only have central symmetry, to each other, about a third reference point located therebetween, but also have mirror symmetry to each other with respect to the third reference point; and
a coordinate value of the third reference point in the second direction and a coordinate value of the second reference point in the second direction are set such that a difference between these two coordinate values is a second constant.
20. The overlay alignment mark according to clause 19, wherein an overlay error between different layers of the wafer comprises:
an overlay error between the first layer and the second layer, at least comprising: a deviation between the first layer and the second layer in the first direction, which is defined by subtracting the first constant from a deviation between the first pattern and the second pattern in the first direction; and
an overlay error between the third layer and the second layer, at least comprising: a deviation between the third layer and the second layer in the second direction, which is defined by subtracting the second constant from a deviation between the third pattern and the second pattern in the second direction.
21. The overlay alignment mark according to clause 20, wherein,
the deviation between the first pattern and the second pattern in the first direction is defined as ½ of a difference between distances between respective centerlines of the two first solid sub-patterns parallel to the second direction and the second reference point; and
the deviation between the first pattern and the second pattern in the second direction is defined as ½ of a difference between distances between respective centerlines of the two second solid sub-patterns parallel to the first direction and the second reference point.
22. The overlay alignment mark according to clause 21, wherein,
a distance between respective centerline of each of the first solid sub-patterns parallel to the second direction and the second reference point, is defined as:
an absolute value of a difference between a mean value of the coordinate values of respective two opposite side edges of each of the first solid sub-patterns extending in the second direction, in the first direction and the coordinate value of the second reference point in the first direction; and
a distance between respective centerline of each of the second solid sub-patterns parallel to the first direction and the second reference point , is defined as:
an absolute value of a difference between a mean value of the coordinate values of respective two opposite side edges of each of the second solid sub-patterns extending in the first direction, in the second direction and the coordinate value of the second reference point in the second direction.
23. The overlay alignment mark according to clause 21 or 22, wherein each type of the two first hollowed sub-patterns and the two second hollowed sub-patterns is designed to not only have central symmetry to each other about the second reference point but also have mirror symmetry to each other with respect to the second reference point.
24. The overlay alignment mark according to clause 23, wherein,
respective two opposite side edges of each of the first hollowed sub-patterns which are opposite to each other in the first direction both extend in the second direction, and the coordinate value of the second reference point in the first direction is defined as a half of a sum of mean values of coordinate values of respective two opposite side edges of the two first hollowed sub-patterns extending in the second direction, in the first direction; and
respective two opposite side edges of each of the second hollowed sub-patterns which are opposite to each other in the second direction both extend in the first direction, and the coordinate value of the second reference point in the second direction is defined as a half of a sum of mean values of coordinate values of respective two opposite side edges of the two second hollowed sub-patterns extending in the first direction, in the second direction.
25. The overlay alignment mark according to clause 23, wherein,
the second pattern further comprises: a central hollowed sub-pattern, the central hollowed sub-pattern is arranged centrally between the two first hollowed sub-patterns and arranged centrally between the two second sub-patterns, with a geometric center of the central hollowed sub-pattern functions as the second reference point.
26. The overlay alignment mark according to clause 25, wherein the central hollowed sub-pattern is designed as a through-hole having a rectangular section.
27. The overlay alignment mark according to any one of clauses 18 to 26, wherein in a condition that the third layer is located below the first layer:
the first pattern further comprises two third hollowed sub-patterns provided opposite to each other in the second direction, and the two third hollowed sub-patterns at least partially overlap with the two second hollowed sub-patterns, respectively, and
two opposite side edges of each of the two second solid sub-patterns extending in the first direction are at least partially exposed from a respective third hollowed sub-pattern and a respective second hollowed sub-pattern.
28. The overlay alignment mark according to any one of clauses 18 to 26, wherein in a condition that the third layer is located between the first layer and the second layer:
the third pattern further comprises two third hollowed sub-patterns provided opposite to each other in the first direction, and the two third hollowed sub-patterns at least partially overlap with the two first hollowed sub-patterns, respectively,
two opposite side edges of each of the two first solid sub-patterns extending in the second direction are at least partially exposed from a respective third hollowed sub-pattern and in turn a respective first hollowed sub-pattern, and
two opposite side edges of each of the two second solid sub-patterns extending in the first direction are at least partially exposed from a respective second hollowed sub-pattern.
29. A method for measuring overlay error, comprising:
providing the overlay alignment mark according to any one of clauses 1 to 28; and
measuring an overlay error between different layers of the wafer by measuring a deviation between portions of the overlay alignment mark which portions are located in the different layers of the wafer.
30. A method for overlay alignment, comprising:
performing the method according to clause 29; and
compensating for the overlay error between different layers of the wafer, by offsetting the different layers of the wafer relative to each other.
31. A method for measuring overlay error, comprising:
providing an overlay alignment mark on a wafer whose overlay error is to be detected, comprising:
   providing a first pattern, comprising: providing two first solid sub-patterns in a first layer of the wafer, the two first solid sub-patterns being provided opposite to each other in a first direction and extending in a second direction perpendicular to the first direction, respectively; and
   providing a second pattern, comprising: providing two first hollowed sub-patterns and two second hollowed sub-patterns in a second layer above the first layer of the wafer, the two first hollowed sub-patterns being provided opposite to each other in the first direction, and two second hollowed sub-patterns being provided opposite to each other in the second direction, two opposite side edges of each of the two first solid sub-patterns which extend in the second direction being at least partially exposed from a respective one of the two first hollowed sub-patterns, and
measuring an overlay error between different layers of the wafer by measuring a deviation between portions of the overlay alignment mark which portions are located in the different layers of the wafer.

32. The method for measuring overlay error according to clause 31, wherein
providing two first solid sub-patterns in a first layer of the wafer further comprises: designing the two first solid sub-patterns to be in the form of two solid patterns having strip-shaped sections, both of which not only have central symmetry, to each other, about a first reference point located therebetween, but also have mirror symmetry to each other with respect to the first reference point;
providing two first hollowed sub-patterns and two second hollowed sub-patterns in a second layer above the first layer of the wafer further comprises: designing one type of the two first hollowed sub-patterns and the two second hollowed sub-patterns to be in the form of two through-holes having rectangular sections, which not only have central symmetry to each other about a second reference point located therebetween but also have mirror symmetry to each other with respect to the second reference point; and
a coordinate value of the first reference point in the first direction and a coordinate value of the second reference point in the first direction are set such that a difference between these two coordinate values is a first constant.
33. The method for measuring overlay error according to clause 32, wherein measuring an overlay error between different layers of the wafer by measuring a deviation between portions of the overlay alignment mark which portions are located in the different layers of the wafer at least comprises:
obtaining a deviation between the first layer and the second layer in the first direction, by subtracting the first constant from a deviation between the first pattern and the second pattern in the first direction as measured.
34. The method for measuring overlay error according to clause 33, wherein
the deviation between the first pattern and the second pattern in the first direction as measured is obtained, by measuring a difference between the coordinate value of the first reference point in the first direction and the coordinate value of the second reference point in the first direction.
35. The method for measuring overlay error according to clause 34, wherein
the coordinate value of the first reference point in the first direction is obtained, by measuring a half of a sum of mean values of coordinate values of respective two opposite side edges of the two first solid sub-patterns extending in the second direction, in the first direction.
36. The method for measuring overlay error according to clause 34 or 35, wherein the two second hollowed sub-patterns are designed such that they not only have central symmetry, to each other, about the second reference point, but also have mirror symmetry to each other with respect to the second reference point.
37. The method for measuring overlay error according to clause 36, wherein the coordinate value of the second reference point in the first direction is obtained, by performing graphical fitting for the two second hollowed sub-patterns into circle patterns or ellipse patterns respectively, and calculating a mean value of the coordinate values, in the first direction, of the geometric centers of the circle patterns or ellipse patterns
38. The method for measuring overlay error according to clause 36 or 37, wherein two pairs of hollowed features are formed in the second layer, with two imaginary lines connecting between geometric centers of respective pairs in the two pairs of hollowed features extending in two mutually orthogonal directions, respectively; and a pair of solid features which are at least partially exposed from a respective pair of the hollowed features are formed in the first layer, with the pair of solid features having respective strip-shaped sections extending in one of the two mutually orthogonal directions, respectively, and
the pair of solid features then function as the two first solid sub-patterns, and the respective pair of the hollowed features from which the pair of solid features are at least partially exposed then function as the two first hollowed sub-patterns, while the other pair of the hollowed features function as the second hollowed sub-patterns.
39. The method for measuring overlay error according to clause 32, wherein
providing a first pattern further comprises: providing two second solid sub-patterns in the first layer of the wafer, the two second solid sub-patterns being provided opposite to each other in the second direction and extending in the first direction respectively, and two opposite side edges of each of the two second solid sub-patterns which extend in the first direction being at least partially exposed from a respective one of the two second hollowed sub-patterns.
40. The method for measuring overlay error according to clause 39, wherein
providing two second solid sub-patterns in the first layer of the wafer further comprises: designing the two second solid sub-patterns to be in the form of two solid patterns having strip-shaped sections, both of which not only have central symmetry, to each other, about the first reference point, but also have mirror symmetry to each other with respect to the first reference point, with a coordinate value of the first reference point in the second direction and a coordinate value of the second reference point in the second direction being set such that a difference between these two coordinate values is a second constant
41. The method for measuring overlay error according to clause 40, wherein
measuring an overlay error between different layers of the wafer by measuring a deviation between portions of the overlay alignment mark which portions are located in the different layers of the wafer at least comprises:
obtaining a deviation between the first layer and the second layer in the first direction, by subtracting the first constant from a deviation between the first pattern and the second pattern as measured in the first direction; and
obtaining a deviation between the first layer and the second layer in the second direction, by subtracting the second constant from a deviation between the first pattern and the second pattern as measured in the second direction.
42. The method for measuring overlay error according to clause 41, wherein measuring a deviation between the first pattern and the second pattern in the first direction comprises: measuring ½ of a difference between distances between respective centerlines of the two first solid sub-patterns parallel to the second direction and the second reference point; and
measuring a deviation between the first pattern and the second pattern in the second direction comprises: measuring ½ of a difference between distances between respective centerlines of the two second solid sub-patterns parallel to the first direction and the second reference point.
43. The method for measuring overlay error according to clause 32, further comprising: providing a third pattern comprising: providing two second solid sub-patterns in a third layer of the wafer which layer is located below the first layer of the wafer or located between the first layer and the second layer, the two second solid sub-patterns being provided opposite to each other in the second direction and extending in the first direction respectively, and two opposite side edges of each of the two second solid sub-patterns extending in the first direction being at least partially exposed from a respective one of the two second hollowed sub-patterns.
44. The method for measuring overlay error according to clause 43, wherein providing two second solid sub-patterns in a third layer of the wafer which layer is located below the first layer of the wafer or located between the first layer and the second layer further comprises: designing the two second solid sub-patterns to be in the form of two solid patterns having strip-shaped sections, both of which not only have central symmetry, to each other, about the third reference point, but also have mirror symmetry to each other with respect to the third reference point, with a coordinate value of the third reference point in the second direction and a coordinate value of the second reference point in the second direction being set such that a difference between these two coordinate values is a second constant
45. The method for measuring overlay error according to clause 44, wherein measuring an overlay error between different layers of the wafer by measuring a deviation between portions of the overlay alignment mark which portions are located in the different layers of the wafer at least comprises:
obtaining a deviation between the first layer and the second layer in the first direction, by subtracting the first constant from a deviation between the first pattern and the second pattern as measured in the first direction; and
obtaining a deviation between the third layer and the second layer in the second direction, by subtracting the second constant from a deviation between the third pattern and the second pattern as measured in the second direction.
46. The method for measuring overlay error according to clause 45, wherein
measuring a deviation between the first pattern and the second pattern in the first direction comprises: measuring ½ of a difference between distances between respective centerlines of the two first solid sub-patterns parallel to the second direction and the second reference point, the respective centerlines of the two first solid sub-patterns being defined by respective two opposite side edges of each of the first solid sub-patterns extending in the second direction; and
measuring a deviation between the third pattern and the second pattern in the second direction Y comprises: measuring ½ of a difference between distances between respective centerlines of the two second solid sub-patterns parallel to the first direction and the second reference point, the respective centerlines of the two second solid sub-patterns being defined by respective two opposite side edges of each of the second solid sub-patterns extending in the first direction.
47. The method for measuring overlay error according to any one of clauses 43 to 46, wherein in a condition that the third layer is located below the first layer, providing a first pattern further comprises: providing two third hollowed sub-patterns in the first layer, the two third hollowed sub-patterns being provided opposite to each other in the second direction and at least partially overlapping with the two second hollowed sub-patterns, and two opposite side edges of each of the two second solid sub-patterns extending in the first direction being at least partially exposed from a respective third hollowed sub-pattern and a respective second hollowed sub-pattern.
48. The method for measuring overlay error according to any one of clauses 43 to 46, wherein in a condition that the third layer is located between the first layer and the second layer, providing a third pattern further comprises: providing two third hollowed sub-patterns in the third layer, the two third hollowed sub-patterns being provided opposite to each other in the first direction and at least partially overlapping with the two first hollowed sub-patterns, two opposite side edges of each of the two first solid sub-patterns extending in the second direction being at least partially exposed from a respective third hollowed sub-pattern, and two opposite side edges of each of the two second solid sub-patterns extending in the first direction being at least partially exposed from a respective second hollowed sub-pattern.

As compared with relevant art, the embodiments of the present disclosure at least have the following superior technical effects:

An overlay alignment mark, a method for measuring overlay error, and a method for overlay alignment are provided in the embodiments of the present disclosure. By providing the overlay alignment mark as described in the embodiments of the present disclosure, setting through-holes in the current layer or even at least one previous layer, and setting solid sub-patterns (such as linear sub-patterns and the like) in at least one previous layer which are arranged in layer(s) different from the layer(s) where the through-holes are located and at least partially overlap with the through-holes respectively, then, the solid sub-patterns are observable through respective through-holes at least partially overlapping therewith, so as to avoid moving the SEM apparatus for many times during a layer-by-layer acquisition of SEM images by scanning thereby and any interference thus caused on measurement of the overlay error as applied by a displacement of the SEM apparatus relative to specific locations of the wafer expected to be scanned by electron beam emitted from the SEM apparatus, then it is not necessary to adjust energy of the electron beam of the SEM apparatus for many times; and by such a setting, then, sub-images imaged from respective sub-patterns in the at least one previous layer at least partially overlapping over the through-holes in the overlay alignment mark can be obtained, by acquisition of a single-pass SEM image merely for the overlay alignment mark, thus simplifying steps of measuring the overlay error. Thus, a clear image can be obtained by using electron beams of relatively low energy, thus reducing the cost while meeting requirement of accuracy in the measurement of overlay accuracy. In an algorithm for measuring overlay error, (such as using graph centerline or graph fitting to calculate the overlay error, and the like), the influence caused by image noise is effectively diminished, and the accuracy and stability in the measurement of overlay error can also be improved.

Moreover, if a portion of graphic features of existing patterns formed on the current layer and the at least one previous layer can meet requirements of the patterns of the overlay alignment mark as above, then such portion of graphic features can be used to function as the overlay alignment marks, without additionally forming a specialized/dedicated overlay alignment mark. As such, it facilities measurement and calculation of the overlay error, in dependence on geometric patterns on the chip itself rather than relying on any specialized/dedicated overlay alignment mark, and by setting computational formulas and using a CD-SEM apparatus to carry out SEM imaging depending on a preset recipe.

The above are merely exemplary embodiments of the present disclosure, rather than intending to restrict the present application. And any modification, equivalent replacement, improvement, and the like which are made within the spirit and principle of the invention shall be comprised in the protection scope of the invention.

What is claimed is:

1. An overlay alignment mark formed on a wafer to be detected, comprising:
a first pattern located in a first layer of the wafer, the first pattern comprising two first solid sub-patterns which are provided opposite to each other in a first direction and extend in a second direction perpendicular to the first direction, respectively; and
a second pattern located in a second layer, above the first layer, of the wafer, the second pattern comprising two first hollowed sub-patterns which are provided opposite to each other in the first direction and two second hollowed sub-patterns which are provided opposite to each other in the second direction,
wherein two opposite side edges of each of the two first solid sub-patterns extending in the second direction are at least partially exposed from a respective one of the two first hollowed sub-patterns.

2. The overlay alignment mark according to claim 1, wherein,
the two first solid sub-patterns are designed to be in the form of two solid patterns having strip-shaped sections, both of which not only have central symmetry, to each other, about a first reference point located therebetween, but also have mirror symmetry to each other with respect to the first reference point;
one type of the two first hollowed sub-patterns and the two second hollowed sub-patterns is designed to be in the form of two through-holes having rectangular sections, which not only have central symmetry to each other about a second reference point located therebetween but also have mirror symmetry to each other with respect to the second reference point; and
a coordinate value of the first reference point in the first direction and a coordinate value of the second reference point in the first direction are set such that a difference between these two coordinate values is a first constant.

3. The overlay alignment mark according to claim 2, wherein
an overlay error between different layers of the wafer is an overlay error between the first layer and the second layer, at least comprising:
a deviation between the first layer and the second layer in the first direction, which is defined by subtracting the first constant from a deviation between the first pattern and the second pattern in the first direction.

4. The overlay alignment mark according to claim 3, wherein the deviation between the first pattern and the second pattern in the first direction is defined as a difference between the coordinate value of the first reference point in the first direction and the coordinate value of the second reference point in the first direction.

5. The overlay alignment mark according to claim 4, wherein the coordinate value of the first reference point in the first direction is defined as a half of a sum of mean values of coordinate values of respective two opposite side edges of the two first solid sub-patterns extending in the second direction, in the first direction.

6. The overlay alignment mark according to claim 4, wherein the two second hollowed sub-patterns are designed to not only have central symmetry to each other about the second reference point but also have mirror symmetry to each other with respect to the second reference point.

7. The overlay alignment mark according to claim 6, wherein the coordinate value of the second reference point in the first direction is defined as a mean value of coordinate values, in the first direction, of geometric centers of circle patterns or ellipse patterns obtained by fitting from the two second hollowed sub-patterns.

8. The overlay alignment mark according to claim 6, wherein two pairs of hollowed features are formed in the second layer, with two imaginary lines connecting between geometric centers of respective pairs in the two pairs of hollowed features extending in two mutually orthogonal directions, respectively; and a pair of solid features which are at least partially exposed from a respective pair of the hollowed features are formed in the first layer, with the pair of solid features having respective strip-shaped sections extending in one of the two mutually orthogonal directions, respectively, and
the pair of solid features then function as the two first solid sub-patterns, and the respective pair of the hollowed features from which the pair of solid features are at least partially exposed then function as the two first hollowed sub-patterns, while the other pair of the hollowed features function as the second hollowed sub-patterns.

9. The overlay alignment mark according to claim 2, wherein the first pattern further comprises two second solid sub-patterns which are provided opposite to each other in the second direction and extend in the first direction respectively; and
two opposite side edges of each of the two second solid sub-patterns extending in the first direction are at least partially exposed from a respective one of the two second hollowed sub-patterns.

10. The overlay alignment mark according to claim 9, wherein,
the two second solid sub-patterns are designed to be in the form of two solid patterns having strip-shaped sections, both of which not only have central symmetry, to each other, about the first reference point, but also have mirror symmetry to each other with respect to the first reference point; and
a coordinate value of the first reference point in the second direction and a coordinate value of the second reference point in the second direction are set such that a difference between these two coordinate values is a second constant.

11. The overlay alignment mark according to claim 10, wherein
an overlay error between different layers of the wafer is an overlay error between the first layer and the second layer, at least comprising:
a deviation between the first layer and the second layer in the first direction, which is defined by subtracting the first constant from a deviation between the first pattern and the second pattern in the first direction; and
a deviation between the first layer and the second layer in the second direction, which is defined by subtracting the second constant from a deviation between the first pattern and the second pattern in the second direction.

12. The overlay alignment mark according to claim 11, wherein,
the deviation between the first pattern and the second pattern in the first direction is defined as ½ of a difference between distances between respective centerlines of the two first solid sub-patterns parallel to the second direction and the second reference point; and
the deviation between the first pattern and the second pattern in the second direction is defined as ½ of a difference between distances between respective centerlines of the two second solid sub-patterns parallel to the first direction and the second reference point.

13. The overlay alignment mark according to claim 12, wherein,
a distance between respective centerline of each first solid sub-pattern parallel to the second direction and the second reference point, is defined as:
an absolute value of a difference between a mean value of the coordinate values of respective two opposite side edges of each first solid sub-pattern extending in the second direction, in the first direction and the coordinate value of the second reference point in the first direction; and
a distance between respective centerline of each second solid sub-pattern parallel to the first direction and the second reference point, is defined as:
an absolute value of a difference between a mean value of the coordinate values of respective two opposite side edges of each second solid sub-pattern extending in the first direction, in the second direction and the coordinate value of the second reference point in the second direction.

14. The overlay alignment mark according to claim 12, wherein each type of the two first hollowed sub-patterns and the two second hollowed sub-patterns is designed to not only have central symmetry to each other about the second reference point but also have mirror symmetry to each other with respect to the second reference point.

15. The overlay alignment mark according to claim 14, wherein,
the coordinate value of the second reference point in the first direction is defined as a half of a sum of mean values of coordinate values of respective two opposite side edges of the two first hollowed sub-patterns extending in the second direction, in the first direction; and
the coordinate value of the second reference point in the second direction is defined as a half of a sum of mean values of coordinate values of respective two opposite side edges of the two second hollowed sub-patterns extending in the first direction, in the second direction.

16. The overlay alignment mark according to claim 14, wherein,
the coordinate value of the second reference point in the first direction is defined as a mean value of coordinate values, in the first direction, of geometric centers of circle patterns or ellipse patterns obtained by fitting from the two first hollowed sub-patterns; and
the coordinate value of the second reference point in the second direction is defined as a mean value of coordinate values, in the second direction, of geometric centers of circle patterns or ellipse patterns obtained by fitting from the two second hollowed sub-patterns.

17. The overlay alignment mark according to claim 14, wherein,
the second pattern also comprises: a central hollowed sub-pattern, the central hollowed sub-pattern is arranged centrally between the two first hollowed sub-patterns and arranged centrally between the two second sub-patterns, with a geometric center of the central hollowed sub-pattern functioning as the second reference point.

18. The overlay alignment mark according to claim 2, further comprising: a third pattern located in a third layer of the wafer which layer is located below the first layer of the wafer or located between the first layer and the second layer, the third pattern comprising two second solid sub-patterns which are provided opposite to each other in the second direction and extend in the first direction, respectively,
wherein two opposite side edges of each of the two second solid sub-patterns extending in the first direction are at least partially exposed from a respective one of the two second hollowed sub-patterns.

19. The overlay alignment mark according to claim 18, wherein,
the two second solid sub-patterns are designed to be in the form of two solid patterns having strip-shaped sections, both of which not only have central symmetry, to each other, about a third reference point located therebetween, but also have mirror symmetry to each other with respect to the third reference point; and
a coordinate value of the third reference point in the second direction and a coordinate value of the second reference point in the second direction are set such that a difference between these two coordinate values is a second constant.

20. The overlay alignment mark according to claim 19, wherein an overlay error between different layers of the wafer comprises:
an overlay error between the first layer and the second layer, at least comprising: a deviation between the first layer and the second layer in the first direction, which is defined by subtracting the first constant from a deviation between the first pattern and the second pattern in the first direction; and
an overlay error between the third layer and the second layer, at least comprising: a deviation between the third layer and the second layer in the second direction, which is defined by subtracting the second constant from a deviation between the third pattern and the second pattern in the second direction.

21. The overlay alignment mark according to claim 20, wherein,
the deviation between the first pattern and the second pattern in the first direction is defined as ½ of a difference between distances between respective centerlines of the two first solid sub-patterns parallel to the second direction and the second reference point, the respective centerlines of the two first solid sub-patterns being defined by respective two opposite side edges of each first solid sub-pattern extending in the second direction; and
the deviation between the third pattern and the second pattern in the second direction is defined as ½ of a difference between distances between respective centerlines of the two second solid sub-patterns parallel to the first direction and the second reference point, the respective centerlines of the two second solid sub-patterns being defined by respective two opposite side edges of each second solid sub-pattern extending in the first direction.

22. The overlay alignment mark according to claim 20, wherein each type of the two first hollowed sub-patterns and the two second hollowed sub-patterns is designed to not only have central symmetry to each other about the second reference point but also have mirror symmetry to each other with respect to the second reference point.

23. The overlay alignment mark according to claim 22, wherein,
respective two opposite side edges of each of the first hollowed sub-patterns which are opposite to each other in the first direction all extend in the second direction, and the coordinate value of the second reference point in the first direction is defined as a half of a sum of mean values of coordinate values of respective two opposite side edges of the two first hollowed sub-patterns extending in the second direction, in the first direction; and
respective two opposite side edges of each of the second hollowed sub-patterns which are opposite to each other in the second direction all extend in the first direction, and the coordinate value of the second reference point in the second direction is defined as a half of a sum of mean values of coordinate values of respective two opposite side edges of the two second hollowed sub-patterns extending in the first direction, in the second direction.

24. The overlay alignment mark according to claim 22, wherein,
the second pattern further comprises: a central hollowed sub-pattern, the central hollowed sub-pattern is arranged centrally between the two first hollowed sub-patterns and arranged centrally between the two second sub-patterns, with a geometric center of the central hollowed sub-pattern functioning as the second reference point.

25. The overlay alignment mark according to claim 24, wherein the central hollowed sub-pattern is designed as a through-hole having a rectangular section.

26. The overlay alignment mark according to claim 18, wherein in a condition that the third layer is located below the first layer:
the first pattern further comprises two third hollowed sub-patterns provided opposite to each other in the second direction, and the two third hollowed sub-patterns at least partially overlap with the two second hollowed sub-patterns, respectively, and
two opposite side edges of each of the two second solid sub-patterns extending in the first direction are at least partially exposed from a respective third hollowed sub-pattern and a respective second hollowed sub-pattern.

27. The overlay alignment mark according to claim 18, wherein in a condition that the third layer is located between the first layer and the second layer:
the third pattern further comprises two third hollowed sub-patterns provided opposite to each other in the first direction, and the two third hollowed sub-patterns at least partially overlap with the two first hollowed sub-patterns, respectively,
two opposite side edges of each of the two first solid sub-patterns extending in the second direction are at least partially exposed from a respective third hollowed sub-pattern and in turn a respective first hollowed sub-pattern, and
two opposite side edges of each of the two second solid sub-patterns extending in the first direction are at least partially exposed from a respective second hollowed sub-pattern.

28. A method for measuring overlay error, comprising:
providing the overlay alignment mark according to claim 1; and
measuring an overlay error between different layers of the wafer by measuring a deviation between portions of the overlay alignment mark which portions are located in the different layers of the wafer.

29. A method for overlay alignment, comprising:
performing the method according to claim 28; and
compensating for the overlay error between different layers of the wafer, by offsetting the different layers of the wafer relative to each other.
